(19) United States
(12) Patent Application Publication
(10) Pub. No.: US 2026/0182367 A1
(43) Pub. Date: Jun. 25, 2026

(54) SEMICONDUCTOR DEVICE WITH ANTENNA AND METHOD OF MANUFACTURING SEMICONDUCTOR DEVICE WITH ANTENNA

(71) Applicant: 1FINITY Inc., Kawasaki-shi (JP)

(72) Inventors: Junya IKEDA, Atsugi (JP); Yoshihiro NAKATA, Atsugi (JP)

(73) Assignee: 1FINITY Inc., Kawasaki-shi (JP)

(21) Appl. No.: 19/400,526

(22) Filed: Nov. 25, 2025

(30) Foreign Application Priority Data
Dec. 23, 2024 (JP) 2024-226186

(51) Int. Cl. H10W 40/20; H01Q 1/22

(52) U.S. Cl. CPC H10W 40/233; H01Q 1/2283; H10W 70/65; H10W 72/823; H10W 90/401

(57) ABSTRACT

A semiconductor device with an antenna includes: a semiconductor chip having a first chip surface, and a circuit surface located opposite the first chip surface; a heat dissipation part having a first surface, and a second surface located opposite the first surface and in contact with the first chip surface of the semiconductor chip; a wiring board having a first board surface, a second board surface located opposite the first board surface, and a laminate in which an insulating layer formed of a resin and an interconnect layer formed of a metal are laminated, wherein the wiring board covers side surfaces of the heat dissipation part and of the semiconductor chip and the circuit surface of the semiconductor chip, and exposes the first surface of the heat dissipation part at the first board surface; and the antenna provided on the second board surface of the wiring board.

### CROSS-REFERENCE TO RELATED APPLICATIONS

This application is based on and claims priority to Japanese Patent Application No. 2024-226186, filed on Dec. 23, 2024, the entire contents of which are incorporated herein by reference.

### FIELD

The present disclosure relates to a semiconductor device with an antenna and a method of manufacturing a semiconductor device with an antenna.

### BACKGROUND

A semiconductor package includes a heat dissipation part disposed on a wiring board, a semiconductor chip disposed on the heat dissipation part, through holes formed in the wiring board so as to be connected to the heat dissipation part, and conductor balls provided on a surface of the wiring board opposite to a surface on which the heat dissipation part is placed. Some conductor balls are connected to wiring of the wiring board connected to the semiconductor chip by bonding wires. The other conductor balls are connected to the through holes. That is, some conductor balls are used as a signal transmission path, and the other conductor balls are used as a heat dissipation path and a ground path (see Patent Document 1, for example).

### RELATED-ART DOCUMENTS

### Patent Documents

Patent Document 1: Japanese Laid-open Patent Publication No. 2001-028410

### SUMMARY

A semiconductor device with an antenna according to an embodiment of the present disclosure includes a semiconductor chip having a first chip surface, and a circuit surface located opposite the first chip surface; a heat dissipation part having a first surface, and a second surface located opposite the first surface and in contact with the first chip surface of the semiconductor chip; a wiring board having a first board surface located on a first surface side of the heat dissipation part, a second board surface located opposite the first board surface, and a laminate in which an insulating layer formed of a resin and an interconnect layer formed of a metal are alternately laminated, wherein the wiring board covers side surfaces of the heat dissipation part and of the semiconductor chip and the circuit surface of the semiconductor chip, and exposes the first surface of the heat dissipation part at the first board surface; and the antenna provided on the second board surface of the wiring board. The wiring board further includes board connection parts provided in a region of the first board surface located outward of an outer periphery of the semiconductor chip in a plan view, and in a region of the first board surface located inward of the outer periphery of the semiconductor chip and outward of an outer periphery of the first surface of the heat dissipation part in the plan view, a first interconnect connecting the board connection parts to a first terminal provided on the circuit surface of the semiconductor chip, and a second interconnect connecting the antenna to a second terminal provided on the circuit surface of the semiconductor chip.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example of a cross-sectional configuration of a semiconductor device 100 with an antenna according to an embodiment;

FIG. 2 is a partially enlarged view illustrating a portion of the semiconductor device 100 with an antenna;

FIG. 3 is a transparent view illustrating an example of a planar configuration of the semiconductor device 100 with an antenna;

FIG. 4A is a diagram illustrating the arrangements of BGA terminals 150A and 150B according to a modification;

FIG. 4B is a diagram illustrating the arrangements of BGA terminals 150A and 150B according to a modification;

FIG. 5A is a diagram illustrating a manufacturing process of a semiconductor device 100 with an antenna;

FIG. 5B is a diagram illustrating the manufacturing process of the semiconductor device 100 with an antenna;

FIG. 5C is a diagram illustrating the manufacturing process of the semiconductor device 100 with an antenna;

FIG. 5D is a diagram illustrating the manufacturing process of the semiconductor device 100 with an antenna;

FIG. 5E is a diagram illustrating the manufacturing process of the semiconductor device 100 with an antenna;

FIG. 5F is a diagram illustrating the manufacturing process of the semiconductor device 100 with an antenna;

FIG. 5G is a diagram illustrating the manufacturing process of the semiconductor device 100 with an antenna;

FIG. 5H is a diagram illustrating the manufacturing process of the semiconductor device 100 with an antenna;

FIG. 5I is a diagram illustrating the manufacturing process of the semiconductor device 100 with an antenna;

FIG. 5J is a diagram illustrating the manufacturing process of the semiconductor device 100 with an antenna;

FIG. 5K is a diagram illustrating the manufacturing process of the semiconductor device 100 with an antenna;

FIG. 6A is a diagram illustrating a manufacturing process of a semiconductor device 100 with an antenna according to a modification;

FIG. 6B is a diagram illustrating the manufacturing process of the semiconductor device 100 with an antenna according to the modification;

FIG. 6C is a diagram illustrating the manufacturing process of the semiconductor device 100 with an antenna according to the modification;

FIG. 7A is a diagram illustrating an example of a configuration of a semiconductor device 100A with an antenna according to a modification of the embodiment;

FIG. 7B is a diagram illustrating an example of a configuration of a semiconductor device 100B with an antenna according to a modification of the embodiment;

FIG. 8A is a diagram illustrating a manufacturing process of a semiconductor device 100B with an antenna;

FIG. 8B is a diagram illustrating the manufacturing process of the semiconductor device 100B with an antenna;

FIG. 8C is a diagram illustrating the manufacturing process of the semiconductor device 100B with an antenna;

FIG. 8D is a diagram illustrating the manufacturing process of the semiconductor device 100B with an antenna;

FIG. 8E is a diagram illustrating the manufacturing process of the semiconductor device 100B with an antenna;

FIG. 8F is a diagram illustrating the manufacturing process of the semiconductor device 100B with an antenna;

FIG. 8G is a diagram illustrating the manufacturing process of the semiconductor device 100B with an antenna;

FIG. 8H is a diagram illustrating the manufacturing process of the semiconductor device 100B with an antenna; and

FIG. 8I is a diagram illustrating the manufacturing process of the semiconductor device 100B with an antenna.

### DESCRIPTION OF EMBODIMENTS

In recent years, there have been semiconductor packages (Antenna-in-Package: AiP) in which antennas are disposed. A semiconductor package (AiP) in which antennas are disposed is a semiconductor device with an antennas. In a semiconductor device with an antenna, if the operating frequency of the antennas increases, it is difficult to increase the size due to restrictions such as a pitch between the antennas. Therefore, in a configuration in which connection conductors used as a signal transmission path and connection conductors connected to a heat dissipation part are arranged on one surface of a semiconductor chip, design considerations are necessary to secure a current path and a heat dissipation path.

According to one embodiment of the present disclosure, a semiconductor device with an antenna and a method of manufacturing a semiconductor device with an antenna that can secure a heat dissipation path while securing a current path can be provided.

An embodiment to which a semiconductor device with an antenna and a method of manufacturing a semiconductor device with an antenna according to the present disclosure are applied will be described below with reference to the accompanying drawings. In the following description, the same components are denoted by the same reference numerals, and duplicate descriptions thereof may be omitted.

An XYZ coordinate system is defined and used in the following description. A direction parallel to an X-axis (X direction), a direction parallel to a Y-axis (Y direction), and a direction parallel to a Z-axis (Z direction) are orthogonal to one another. The X direction is an example of a first axis direction, the Y direction is an example of a second axis direction, and the Z direction is an example of a third axis direction. Further, in the following description, for the sake of convenience, a −Z side may be referred to as a lower side or below, and a +Z side may be referred to as an upper side or above. In addition, a plan view refers to viewing an object in a direction perpendicular to the XY plane. Further, in the following description, the length, the width, the thickness, and the like of each part may be exaggerated to facilitate the understanding of the configuration. In addition, the terms “parallel”, “perpendicular”, “orthogonal”, “horizontal”, “vertical”, “upper”, “lower”, and the like may tolerate deviations to the extent that does not impair the effects of the embodiment.

Further, in the following description, the term “millimeter wave” or “millimeter wave band” includes not only a frequency band of 30 GHz to 300 GHz but also a quasi-millimeter wave band of 24 GHZ to 30 GHZ.

It is assumed that radio waves transmitted from or received by an antenna of a semiconductor device according to an embodiment are, for example, radio waves in the millimeter wave band of the sixth generation mobile communication system (6G) or the like, in a frequency range of 40 GHz or higher. However, the radio waves transmitted from or received by the antenna may be radio waves in the millimeter wave band of the fifth generation mobile communication system (5G) or the like or radio waves in a frequency range of 1 GHZ to 30 GHZ including Sub-6.

### Embodiment

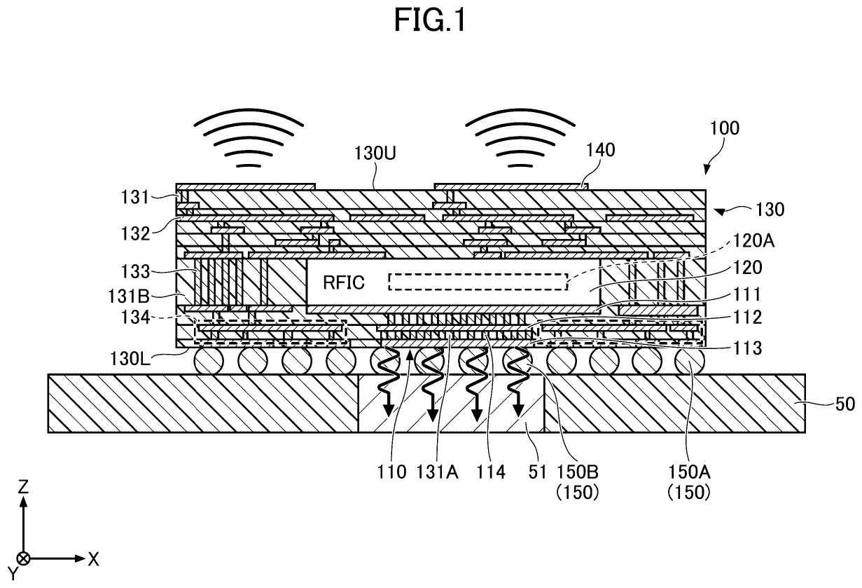

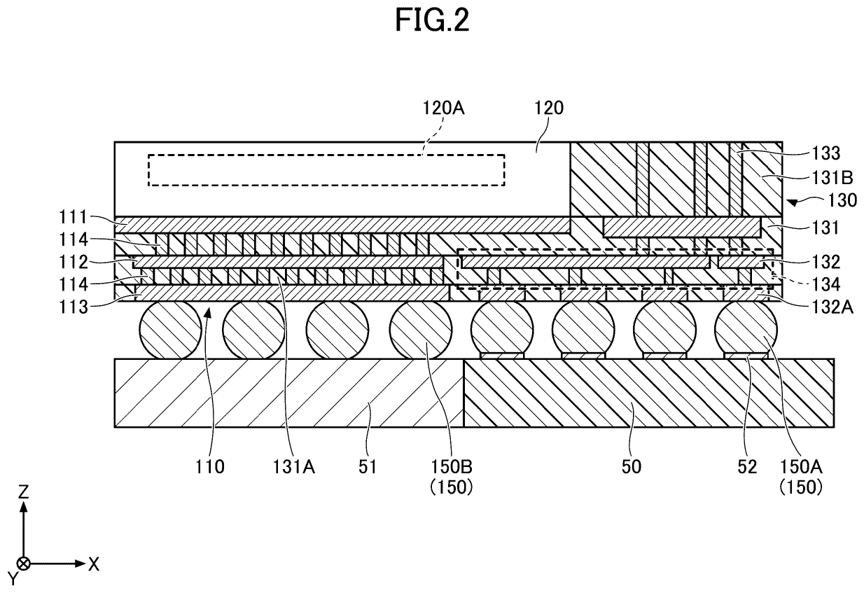

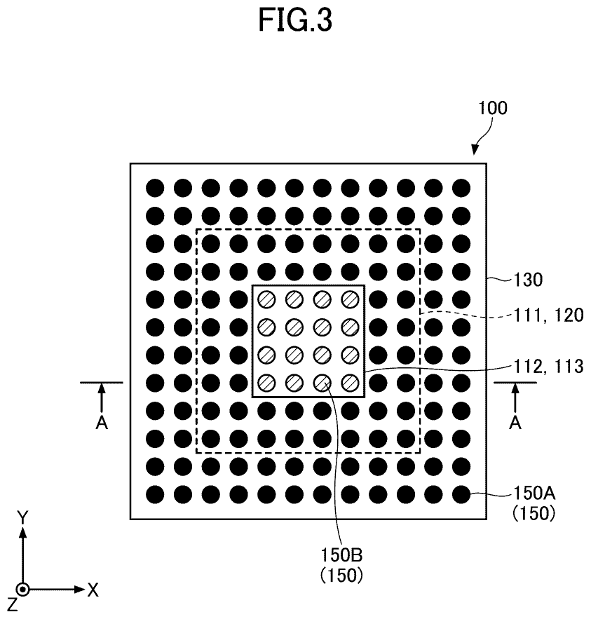

FIG. 1 is a diagram illustrating an example of a cross-sectional configuration of a semiconductor device 100 with an antenna according to an embodiment. FIG. 2 is a partially enlarged view illustrating a portion of the semiconductor device 100 with an antenna. FIG. 3 is a transparent view illustrating an example of a planar configuration of the semiconductor device 100 with an antenna. The cross section illustrated in FIG. 1 is a cross section taken along line A-A of FIG. 3.

FIG. 3 illustrates a positional relationship among metal layers 111, 112, and 113 of a heat dissipation part 110, a semiconductor chip 120, a wiring board 130, and a plurality of ball grid array (BGA) terminals 150 (150A and 150B) in a transparent manner. In FIG. 3, an antenna 140 is not depicted. In FIG. 3, the outer periphery of the metal layer 111 and the outer periphery of the semiconductor chip 120 are indicated by a dashed line, and the outer periphery of the metal layers 112 and 113 and the outer periphery of the wiring board 130 are indicated by solid lines.

<Semiconductor Device 100 with Antenna>

The semiconductor device 100 with an antenna includes the heat dissipation part 110, the semiconductor chip 120, the wiring board 130, the antenna 140, and the plurality of ball grid array (BGA) terminals 150. The semiconductor device 100 with an antenna is mounted on a radio frequency (RF) board 50 via the BGA terminals 150 (150A and 150B). The BGA terminals 150A and 150B are hereinafter simply referred to as the “BGA terminals 150” when they are not particularly distinguished.

The semiconductor device 100 with an antenna is a semiconductor package (Antenna-in-Package: AiP) including the antenna 140 as an RF antenna in the package. As an example, the semiconductor device 100 with an antenna may be a wireless communication device that can be mounted on a radio unit (RU) of a front end of a base station, and the RF board 50 may be a mother board of the base station.

The AiP is configured to cause the semiconductor chip 120 provided therein to amplify a signa, and radiate radio waves from the antenna 140. In recent applications for 5G and later generations, utilization of millimeter wave band frequencies is in progress in order to support ultra high-speed communication, ultra-low latency, and multiple simultaneous connections. In order to achieve high output power in the AiP for the base station, it is necessary to dispose an RF chip including a heat generating part such as a power amplifier in the vicinity of the antenna 140, such that radio waves with a low loss and a high output can be radiated from the antenna 140. In order to meet such requirements, the semiconductor device 100 with an antenna according to the embodiment can secure a heat dissipation path for efficiently discharging heat from the semiconductor chip 120 to the outside while securing a current path to the semiconductor chip 120.

The RF board 50 includes a heat dissipation plate 51 and terminals 52. The heat dissipation plate 51 is provided in the RF board 50, and is connected to the heat dissipation part 110 of the semiconductor device 100 with an antenna via the BGA terminals 150B. The heat dissipation plate 51 is provided so as to dissipate heat, transferred from the heat dissipation part 110 through the BGA terminals 150B, to the outside of the RF board 50. The heat dissipation plate 51 is preferably formed of a metal having a high thermal conductivity. As an example, the heat dissipation plate 51 may be formed of a metal such as aluminum or copper.

The terminals 52 are provided on the upper surface of the RF board 50, and are connected to an interconnect layer 132 of the wiring board 130 via the BGA terminals 150A and to terminals on the upper surface (a circuit surface) of the semiconductor chip 120 via vias 133. The terminals on the upper surface of the semiconductor chip 120 are connected to a circuit 120A inside the semiconductor chip 120.

### <Heat Dissipation Part 110>

The heat dissipation part 110 includes the metal layers 111, 112, and 113, vias 114, and an insulating layer 131A. The metal layer 111 is an example of a first metal layer, and the metal layer 113 is an example of a second metal layer. The insulating layer 131A is an example of an interlayer insulating layer. If the heat dissipation part 110 includes the metal layers 111 and 112 and does not include the metal layer 113, the metal layer 112 is an example of the second metal layer.

The metal layer 111 is provided on the lower surface (an example of a first chip surface) of the semiconductor chip 120. That is, the upper surface of the metal layer 111 is in contact with the lower surface of the semiconductor chip 120. The upper surface of the metal layer 111 is an example of a second surface of the heat dissipation part 110.

As an example, the metal layer 111 is provided on the entire lower surface of the semiconductor chip 120. Therefore, as illustrated in FIG. 3, the outer periphery of the metal layer 111 coincides with the outer periphery of the semiconductor chip 120 in a plan view.

As an example, because the metal layer 111 is provided on the entire lower surface of the semiconductor chip 120, heat generated in the entire semiconductor chip 120 can be efficiently collected. The metal layer 111 need not be provided on the entire lower surface of the semiconductor chip 120, and may be provided on a portion of the lower surface of the semiconductor chip 120.

The metal layer 112 is provided between the metal layers 111 and 113 via the insulating layer 131A. The insulating layer 131A is located between the metal layers 111 and 112 and between the metal layers 112 and 113. The metal layers 111 and 112, and the metal layers 112 and 113 are connected by the vias 114 penetrating through the insulating layer 131A in the Z direction. That is, the metal layers 111, 112 and 113 are connected by the vias 114 penetrating through the insulating layer 131A in the Z direction.

As an example, the metal layer 112 is smaller than the metal layer 111 in a plan view. As used herein, the expression “the metal layer 112 is smaller than the metal layer 111 in a plan view” means that the sizes differ to the extent that some of the plurality of BGA terminals 150, which are arranged at an equal pitch in the X direction and the Y direction in a plan view, are located between the outer periphery of the metal layer 111 and the outer periphery of the metal layer 112 in the X direction or the Y direction.

In a plan view, the outer periphery of the metal layer 112 is enclosed in the outer periphery of the metal layer 111. The length of the metal layer 112 in the X direction and the Y directions is, for example, about one-half of the length of the metal layer 111 in the X direction and the Y direction, and the size of the metal layer 112 is, for example, about one-fourth of the size of the metal layer 111.

The metal layer 113 is provided under the metal layer 112 via the insulating layer 131A. The metal layer 113 is exposed at the lower surface of the wiring board 130, and the BGA terminals 150B are connected to the lower surface of the metal layer 113. The lower surface of the metal layer 113 is an example of a first surface of the heat dissipation part 110.

As an example, the metal layer 113 is smaller than the metal layer 111 in a plan view, and has the same size and the same shape as the metal layer 112. In a plan view, the outer periphery of the metal layer 113 is enclosed in the outer periphery of the metal layer 111 and coincides with the outer periphery of the metal layer 112. Further, in this case, the heat dissipation plate 51 of the RF board 50 has the same size and the same shape as the metal layers 112 and 113 in a plan view, and the position of the heat dissipation plate 51 may overlap the positions of the metal layers 112 and 113 in a plan view.

The metal layer 113 is connected to the heat dissipation plate 51 via the BGA terminals 150B. Therefore, the heat dissipation part 110 functions as a heat dissipation path for transmitting heat generated by the semiconductor chip 120 to the heat dissipation plate 51.

Vias 114 penetrating through the insulating layer 131A, the metal layer 112, and vias 114 penetrating through the insulating layer 131A are provided between the metal layer 111, which is the example of the first metal layer, and the metal layer 113, which is the example of the second metal layer, from the metal layer 111 side to the metal layer 113 side. The expression that the metal layer 111, which is the example of the first metal layer, and the metal layer 113, which is the example of the second metal layer, are connected to each other via the vias 114 includes a state in which the metal layers 111 and 113 are connected to each other by the vias 114 with the metal layer 112 interposed therebetween. The same applies to a case where two or more metal layers 112 are provided between the metal layers 111 and 113.

The side surfaces of the heat dissipation part 110 are covered by the wiring board 130, and the lower surface of the heat dissipation part 110 (the lower surface of the metal layer 113) is exposed at the lower surface of the wiring board 130. As an example, the heat dissipation part 110 is located at a position identical to the position of a matching circuit 134 in the height direction (Z direction). The matching circuit 134 is located at the lowermost portion of the wiring board 130. As an example, the heat dissipation part 110 is formed of a metal material that is the same as a metal material used for interconnect layers 132 and vias 133 forming the matching circuit 134.

That is, the metal layers 111, 112, and 113 are, as an example, metal layers formed by a semiconductor manufacturing process together with interconnect layers 132 of the wiring board 130. Further, the insulating layer 131A of the heat dissipation part 110 is, as an example, an insulating layer formed by a semiconductor manufacturing process together with an insulating layer 131 of the wiring board 130. The metal layers 111, 112, and 113 may be formed of a metal such as copper. A material of the insulating layer 131A will be described later together with a description of the insulating layer 131 of the wiring board 130.

### <Semiconductor Chip 120>

The semiconductor chip 120 is a radio frequency integrated circuit (RFIC) manufactured by a semiconductor manufacturing process, and is manufactured based on a silicon substrate or the like, as an example. The semiconductor chip 120 is provided on the heat dissipation part 110. The semiconductor chip 120 has the lower surface, which is in contact with the upper surface of the heat dissipation part 110, and the upper surface, and includes the circuit 120A provided inside the semiconductor chip 120. The upper surface of the semiconductor chip 120 is the circuit surface. The circuit surface is provided with terminals for connecting to interconnect layers 132 of the wiring board 130.

The circuit 120A is a circuit for wireless communication, such as a power amplifier for transmission or a low-noise amplifier (LNA) for reception, and is connected to the terminals on the circuit surface via interconnects or the like (not illustrated).

### <Wiring Board 130>

The wiring board 130 has a lower surface 130L and an upper surface 130U, and includes insulating layers 131, interconnect layers 132, vias 133, and the matching circuit 134. The lower surface 130L is an example of a first board surface, and the upper surface 130U is an example of a second board surface. The wiring board 130 has a configuration in which a plurality of insulating layers 131 and a plurality of interconnect layers (the interconnect layers 132 and the matching circuit 134) are alternately laminated, and the plurality of interconnect layers (the interconnect layers 132 and the matching circuit 134) are connected by the vias 133. The wiring board 130 having such a configuration can be manufactured by a redistribution layer manufacturing process.

As illustrated in FIG. 3, the size of the wiring board 130 is larger than the size of each of the heat dissipation part 110 and the semiconductor chip 120 in a plan view, and the height of the wiring board 130 is greater than the height of each of the heat dissipation part 110 and the semiconductor chip 120 in the Z direction. The wiring board 130 covers the side surfaces of the heat dissipation part 110 and of the semiconductor chip 120 and the circuit surface (upper surface) of the semiconductor chip 120 located opposite the heat dissipation part 110, and exposes the metal layer 113 of the heat dissipation part 110 at the lower surface 130L.

Among the plurality of insulating layers 131, one insulating layer 131 located at the same height as the semiconductor chip 120 is distinguished as an insulating layer 131B. The insulating layer 131B is one of the plurality of insulating layers 131 included in the wiring board 130, and is an insulating layer having the largest thickness among the plurality of insulating layers 131. As an example, insulating layers 131 other than the insulating layer 131B have a structure that uses a film material (for example, an ABF material manufactured by Ajinomoto Fine-Techno Co., Inc.) in which a filler such as alumina is mixed into an epoxy resin, or a resin film material such as a polyimide film. The insulating layer 131B can be formed of a molding material in which a filler such as alumina is mixed into an epoxy resin or the like. However, similar to the insulating layers 131 other than the insulating layer 131B, the insulating layer 131B may have a structure that uses a film material in which a filler such as alumina is mixed into an epoxy resin, or a resin film material such as a polyimide film.

The interconnect layers 132 are formed of, for example, copper (copper foil patterns), and are all of the plurality of interconnect layers of the wiring board 130. At least some portions of the lowermost interconnect layer 132 of the wiring board 130, among the interconnect layers 132, are used as terminals 132A (see FIG. 2). The terminals 132A are an example of board connection parts. The BGA terminals 150A are connected to the terminals 132A. Further, the metal layers 111 to 113 of the heat dissipation part 110 are formed together with the interconnect layers 132 by a redistribution layer manufacturing process.

The vias 133 are formed of, for example, copper, and connect the plurality of interconnect layers 132 to one another. The vias 133 are through vias having a small diameter. The vias 114 of the heat dissipation part 110 are manufactured together with the vias 133 by a redistribution layer manufacturing process.

The matching circuit 134 is formed by one or more interconnect layers 132 located at the lowest position among all of the plurality of interconnect layers 132 provided in the wiring board 130, and vias 133. The matching circuit 134 is formed of copper, for example. The matching circuit 134 is a matching circuit provided so as to achieve impedance matching between the BGA terminals 150A and the interconnect layers 132 and vias 133. For example, the matching circuit 134 includes capacitance components and inductance components that are formed by copper foil patterns, for example.

In the wiring board 130 having the configuration described above, interconnects (an example of a first interconnect) formed by some of the insulating layers 131, the interconnect layers 132, the vias 133, and the matching circuit 134, connect a first terminal of a plurality of terminals provided on the circuit surface of the semiconductor chip 120 to the terminals 132A at the lowermost layer of the wiring board 130. The terminals 132A are connected to the terminals 52 of the RF board 50 via the BGA terminals 150A. The interconnects that are the example of the first interconnect serve as a transmission path for a control signal of the circuit 120A, a signal transmitted or received via the antenna 140, and the like, and also serve as a power supply path to the circuit 120A.

Further, interconnects (an example of a second interconnect) formed by some of the insulating layers 131, the interconnect layer 132, and the vias 133 connect a second terminal of the plurality of terminals provided on the circuit surface of the semiconductor chip 120 to a plurality of antennas 140. The interconnects that are the example of the second interconnect serve as a power supply line for the antennas 140.

### <Antennas 140>

The antennas 140 are a plurality of patch antennas provided on the upper surface 130U of the wiring board 130. Similar to the interconnect layers 132 and the vias 133, the antennas 140 are formed of, for example, copper. The antennas 140 can be formed as copper foil patterns by a redistribution layer manufacturing process. As an example, a configuration in which the semiconductor device 100 with an antenna includes four antennas 140 will be described, but the semiconductor device 100 with an antenna may include at least two or more antennas 140.

The four antennas 140 are arranged such that two antennas 140 are arranged at an equal pitch in the X direction and two antennas 140 are arranged at an equal pitch in the Y direction. Radio waves radiated from the four antennas 140 form a single beam by beam forming, and an angle of the beam can be varied by controlling phases of the radio waves radiated from the four antennas 140 by the circuit 120A.

### <BGA Terminals 150>

The plurality of BGA terminals 150 include the BGA terminals 150A and the BGA terminals 150B, and the BGA terminals 150A and the BGA terminals 150B are of the same type, for example. The BGA terminals 150 of the same type refer to BGA terminals having the same size and formed of the same material and can be used without being distinguished from each other.

The BGA terminals 150A are used to transmit signals, power, and the like, and the BGA terminals 150B are used as a heat dissipation path.

In particular, in the case of transmitting radio waves in the millimeter wave band of the sixth generation mobile communication system (6G) or the like, in the frequency band of 40 GHz or higher, it is necessary to supply a large amount of current to a power amplifier included in the circuit 120A. Because the amount of current per BGA terminal 150A is limited, a large number of BGA terminals 150A is required. The same applies to the case of transmitting radio waves in the millimeter wave band of the fifth generation mobile communication system (5G) or the like or radio waves in the frequency band of 1 GHZ to 30 GHZ including Sub-6.

In addition, from the viewpoint of securing a heat dissipation path, it is necessary to secure a certain number of BGA terminals 150B.

### <Securing Current Path>

In order to secure a current path, the semiconductor device 100 with an antenna has a configuration in which the number of BGA terminals 150A is increased.

As illustrated in FIG. 3, the BGA terminals 150A are BGA terminals 150 located outward of the outer peripheries of the metal layers 112 and 113 of the heat dissipation part 110, among all the BGA terminals 150. As illustrated in FIG. 1 and FIG. 2, the BGA terminals 150A connect the terminals 132A of the wiring board 130 and the terminals 52 of the RF board 50.

Among all the BGA terminals 150A, BGA terminals 150A located on the center region of the wiring board 130 in a plan view are located inward of the outer periphery of the semiconductor chip 120 and outward of the outer peripheries of the metal layers 112 and 113 in a plan view. The BGA terminals 150A located inward of the outer periphery of the semiconductor chip 120 are located under the semiconductor chip 120. By providing the BGA terminals 150A inward of the outer periphery of the semiconductor chip 120 in this manner, the number of BGA terminals 150A can be increased. By increasing the number of the BGA terminals 150A, the capacitance of a current path can be increased, and a large amount of current can be supplied to the circuit 120A through the BGA terminals 150A.

For example, as compared to when BGA terminals 150A are arranged only outward of the semiconductor chip 120 in a plan view, the number of BGA terminals 150A can be significantly increased when the BGA terminals 150A are also arranged under the semiconductor chip 120 as in the semiconductor device 100 with an antenna.

In the semiconductor device 100 with an antenna, the BGA terminals 150A are arranged not only outward of the outer periphery of the semiconductor chip 120 but also inward of the outer periphery of the semiconductor chip 120 and outward of the outer peripheries of the metal layers 112 and 113 in a plan view. Thus, a current path that can handle a large amount of current can be secured. The large amount of current is the amount of current that needs to be supplied to a power amplifier in order to obtain a radiation distance of radio waves in the millimeter wave band of the sixth generation mobile communication system (6G) or the like in the frequency band of 40 GHz or higher, radio waves in the millimeter wave band of the fifth generation mobile communication system (5G) or the like, or radio waves in the frequency band of 1 GHZ to 30 GHZ including Sub-6.

### <Securing Heat Dissipation Path>

In order to secure a heat dissipation path, it is desirable that the heat dissipation part 110 and the heat dissipation plate 51 of the RF board 50 are disposed close to each other and are connected to each other with a low thermal resistance.

In the semiconductor device 100 with an antenna, in order to secure a heat dissipation path, the heat dissipation part 110 is provided directly under the semiconductor chip 120, and the heat dissipation part 110 and the heat dissipation plate 51 are connected only by the plurality of BGA terminals 150B. Further, the heat dissipation part 110 has a configuration in which the metal layers 111 to 113 are connected by a number of vias 114.

As illustrated in FIG. 3, the BGA terminals 150B are BGA terminals located inward of the outer peripheries of the metal layers 112 and 113 of the heat dissipation part 110, among all the BGA terminals 150. As illustrated in FIG. 1 and FIG. 2, the BGA terminals 150B connect the lower surface of the metal layer 113 of the heat dissipation part 110 and the upper surface of the heat dissipation plate 51 of the RF board 50.

Therefore, the heat dissipation part 110 is connected to the heat dissipation plate 51 only via the BGA terminals 150B. Heat from the heat dissipation part 110 is transmitted to the heat dissipation plate 51 via the BGA terminals 150B and is dissipated from the heat dissipation plate 51 into the air. Further, some heat is dissipated from the heat dissipation part 110 and the BGA terminals 150B into the air.

As described above, the heat dissipation part 110 exposed at the lower surface of the semiconductor device 100 with an antenna is connected to the heat dissipation plate 51 of the RF board 50 through the shortest path by the BGA terminals 150B connected to the lower surface of the metal layer 113. Thus, the heat dissipation part 110 is connected to the heat dissipation plate 51 with a low thermal resistance. Therefore, heat from the heat dissipation part 110 can be efficiently dissipated to the outside of the semiconductor device 100 with an antenna.

Further, because the metal layer 111 of the heat dissipation part 110 is provided on the entire lower surface of the semiconductor chip 120, heat generated in the entire semiconductor chip 120 can be efficiently transmitted to the heat dissipation plate 51. The metal layer 111 is connected to the metal layer 112 by a number of vias 114, and the metal layer 112 is connected to the metal layer 113 by a number of vias 114. Therefore, even if the metal layers 112 and 113 are smaller than the metal layer 111 in a plan view, sufficient heat dissipation capacity can be secured.

As an example, in a configuration in which the metal layer 111 has a square shape with one side of 10 mm in length in a plan view, the metal layer 112 has a square shape with one side of 5 mm in length in a plan view, and the vias 114 each having a diameter of 50 μm are arranged between the metal layers 111 and 112 at a pitch of 200 μm, the thermal resistance between the upper surface of the metal layer 111 and the lower surface of the metal layer 112 was calculated and was about 0.016 K/W. This value was equivalent to the thermal resistance between the upper surface and the lower surface of a heat spreader made of a metal plate having the same size as the semiconductor chip 120 in a plan view. Therefore, the thermal resistance of the heat dissipation part 110 in which the metal layers 111 to 113 are connected by the vias 114 is considered to be similar to the above value.

As described above, by using the heat dissipation part 110 having a configuration in which the metal layers 111 to 113 are connected by the vias 114 and directly connecting the heat dissipation part 110 disposed directly under the semiconductor chip 120 to the heat dissipation plate 51 by the BGA terminals 150B, sufficient heat dissipation can be ensured for the semiconductor chip 120 that generates heat by a large amount of current being supplied.

### <Securing Current Path and Securing Heat Dissipation Path>

The semiconductor device 100 with an antenna can secure a current path while maintaining heat dissipation by including the heat dissipation part 110 having a configuration as described above and the BGA terminals 150A and 150B. Further, because the number of BGA terminals 150A for the current path can be increased without increasing the size of the semiconductor device 100 with an antenna, the size of the semiconductor device 100 with an antenna can be reduced. Further, by increasing the number of BGA terminals 150A for the current path, the transmission speed of signals can be increased.

Although a configuration in which the heat dissipation part 110 includes the three metal layers 111 to 113 has been described above, the heat dissipation part 110 may have a configuration in which the metal layers 111 and 112 are connected by vias 114, or may have a configuration in which four or more metal layers are connected by vias 114.

Further, a configuration in which the metal layer 111 of the heat dissipation part 110 is provided on the entire lower surface of the semiconductor chip 120 has been described above; however, the metal layer 111 may be smaller than the semiconductor chip 120 in a plan view. In a plan view, the size of the metal layer 111 may be the same as the size of the metal layers 112 and 113 or may be smaller than the size of the metal layers 112 and 113, as long as heat dissipation can be ensured. The metal layers 112 and 113 may have different sizes in a plan view.

### <Arrangements of BGA Terminals 150A and 150B According to Modifications>

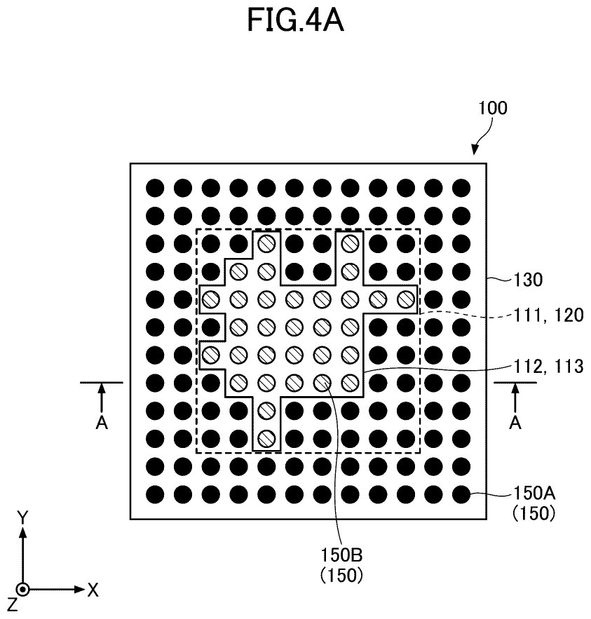

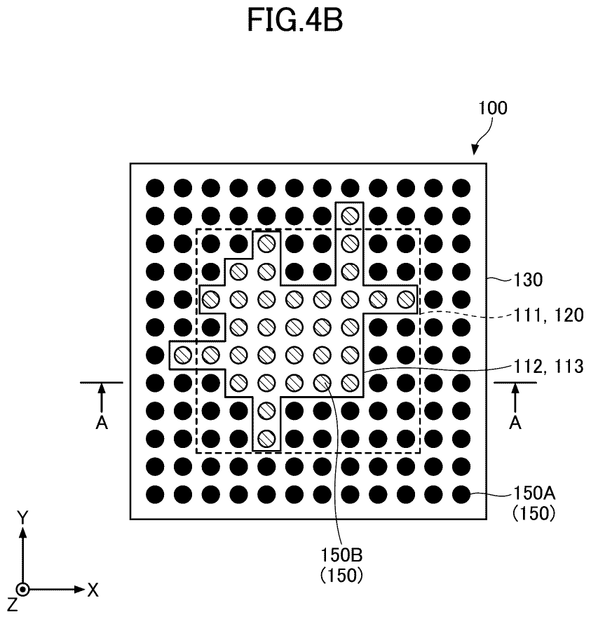

FIG. 4A and FIG. 4B are diagrams each illustrating the arrangement of BGA terminals 150A and 150B according to a modification. The arrangement of the BGA terminals 150A and 150B illustrated in each of FIG. 4A and FIG. 4B is different from the arrangement of the BGA terminals 150A and 150B illustrated in FIG. 3. Because the shape and the position of a metal layer 113 in each of FIG. 4A and FIG. 4B differs from those of the above-described metal layer 113 in a plan view, the arrangement of the BGA terminals 150A and 150B illustrated in each of FIG. 4A and FIG. 4B differs from the arrangement of the BGA terminals 150A and 150B illustrated in FIG. 3.

In the following description, it is assumed that the shapes and the positions of metal layers 112 and 113 are the same, but may be different. Further, because the metal layer 111 is provided on the entire lower surface of the semiconductor chip 120 as an example, the outer periphery of the metal layer 111 coincides with the outer periphery of the semiconductor chip 120 in a plan view.

### <Configuration of FIG. 4A>

Metal layers 112 and 113 illustrated in FIG. 4A are located inward of the outer periphery of the semiconductor chip 120 in a plan view, but the metal layers 112 and 113 have portions (projecting portions) protruding outward relative to the outer peripheries of the metal layers 112 and 113 illustrated in FIG. 3. In a plan view, the outer peripheries of the tips of the projecting portions of the metal layers 112 and 113 coincide with the outer periphery of the semiconductor chip 120.

Further, the outer periphery of each of the metal layers 112 and 113 has a portion having a recessed shape (recessed portion) between two adjacent projecting portions. For example, the outer periphery of each of the metal layers 112 and 113 illustrated in FIG. 3 may have a recessed portion recessed inward.

Further, in a case where the metal layers 112 and 113 have the shape illustrated in FIG. 4A in a plan view, the heat dissipation plate 51 of the RF board 50 may have the same shape.

BGA terminals 150B connect the lower surface of the metal layer 113 of the heat dissipation part 110 and the upper surface of the heat dissipation plate 51 of the RF board 50. Thus, the number of the BGA terminals 150B is increased in FIG. 4A as compared to FIG. 3. However, in the configuration illustrated in FIG. 4A, terminals 150A located under the semiconductor chip 120 are additionally provided, unlike in a configuration in which BGA terminals 150B are provided only outward of the outer periphery of the semiconductor chip 120 in a plan view.

Therefore, similar to the semiconductor device 100 with an antenna having the configuration illustrated in FIG. 3, a semiconductor device 100 with an antenna having the configuration illustrated in FIG. 4A can secure a heat dissipation path while securing a current path.

### <Configuration of FIG. 4B>

In metal layers 112 and 113 illustrated in FIG. 4B, two projecting portions of each of the outer peripheries of the metal layers 112 and 113, among the plurality of projecting portions illustrated in FIG. 4A, protrude outward relative to the outer periphery of the semiconductor chip 120 in a plan view.

In this case, the heat dissipation plate 51 of the RF board 50 may have the same shape and the same size as the shape and the size of the metal layers 112 and 113 in a plan view, and the position of the heat dissipation plate 51 may overlap the positions of the metal layers 112 and 113.

BGA terminals 150B connect the lower surface of the metal layer 113 of the heat dissipation part 110 and the upper surface of the heat dissipation plate 51 of the RF board 50. Thus, the number of the BGA terminals 150B is increased in FIG. 4B as compared to FIG. 3. However, in the configuration illustrated in FIG. 4B, terminals 150A located under the semiconductor chip 120 are additionally provided unlike a configuration in which BGA terminals 150B are provided only outward of the outer periphery of the semiconductor chip 120 in a plan view.

Therefore, similar to the semiconductor device 100 with an antenna having the configuration illustrated in FIG. 3, a semiconductor device 100 with an antenna having the configuration illustrated in FIG. 4B can secure a heat dissipation path while securing a current path.

Further, the lower ends of BGA terminals 150B, which are located at the tips of the projecting portions of the metal layers 112 and 113 illustrated in FIG. 4B and located outward of the outer periphery of the semiconductor chip 120 in a plan view, may be connected to ground terminals of the RF board 50. In this case, the heat dissipation plate 51 need not be provided directly under the BGA terminals 150B located outward of the outer periphery of the semiconductor chip 120, and the ground terminals may be provided directly under the BGA terminals 150B located outward of the outer periphery of the semiconductor chip 120.

When the BGA terminals 150B are connected to the ground terminals of the RF board 50, the metal layers 111 to 113 of the heat dissipation part 110 are maintained at the ground potential. Thus, the impedance of BGA terminals 150A is improved, and signals can be more stably transmitted via the BGA terminals 150A.

<Method of Manufacturing Semiconductor Device 100 with Antenna>

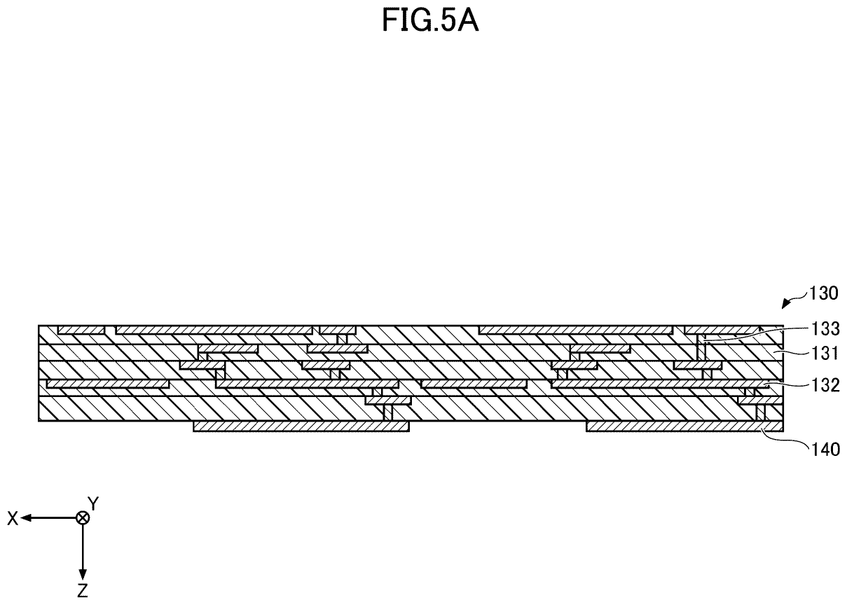

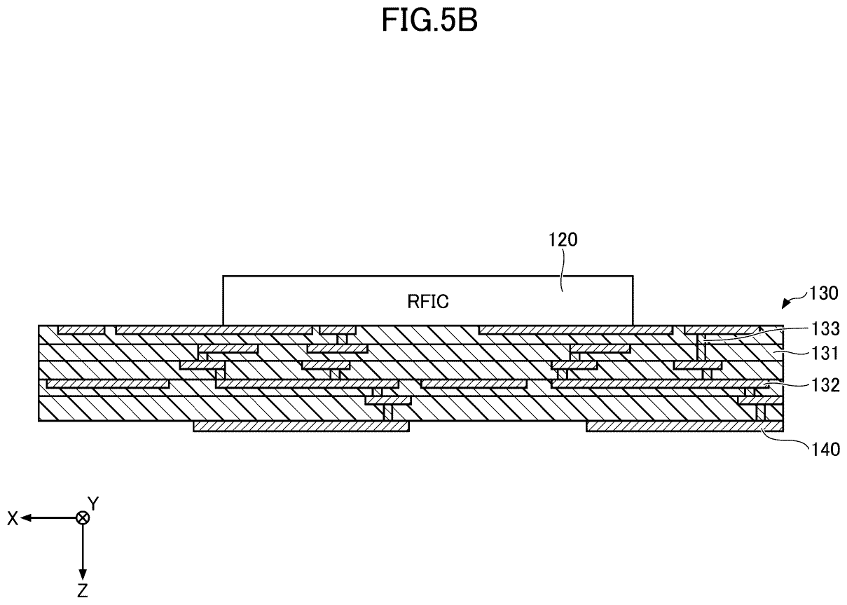

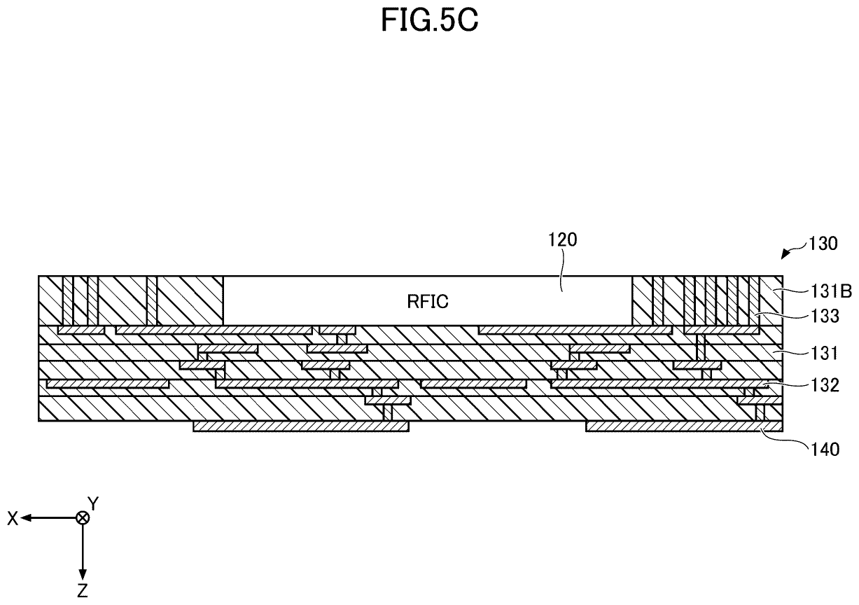

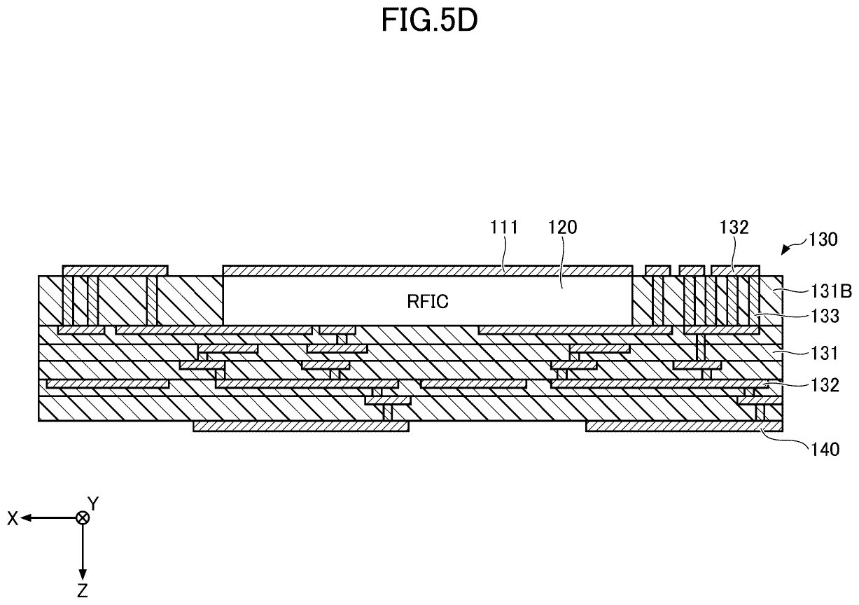

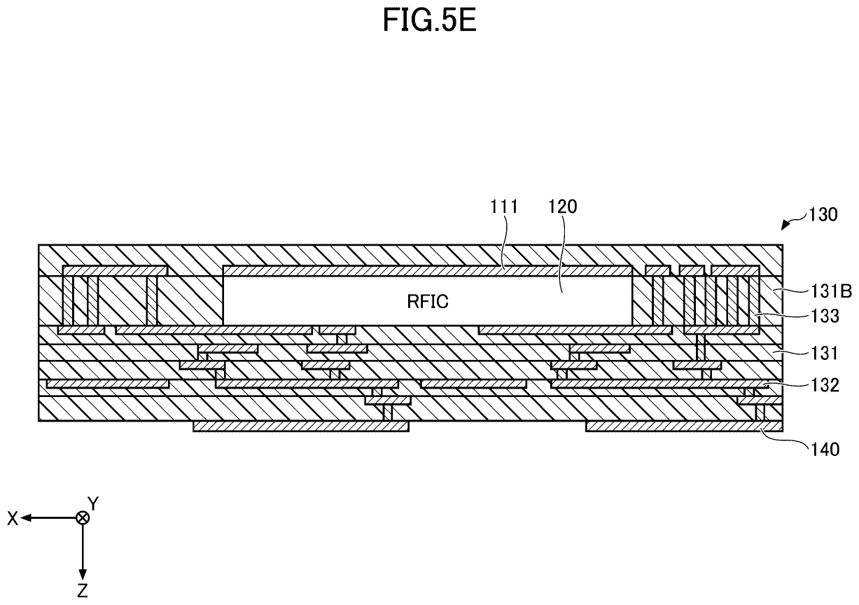

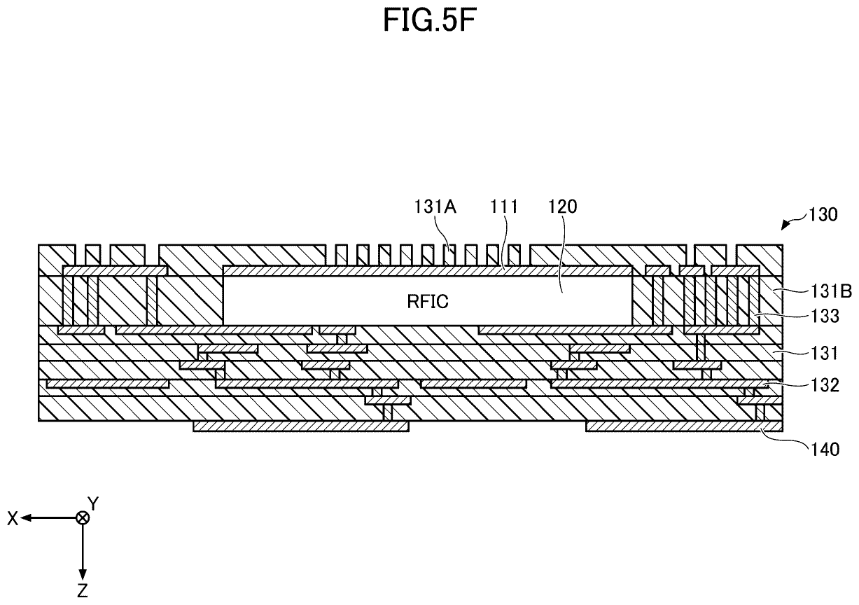

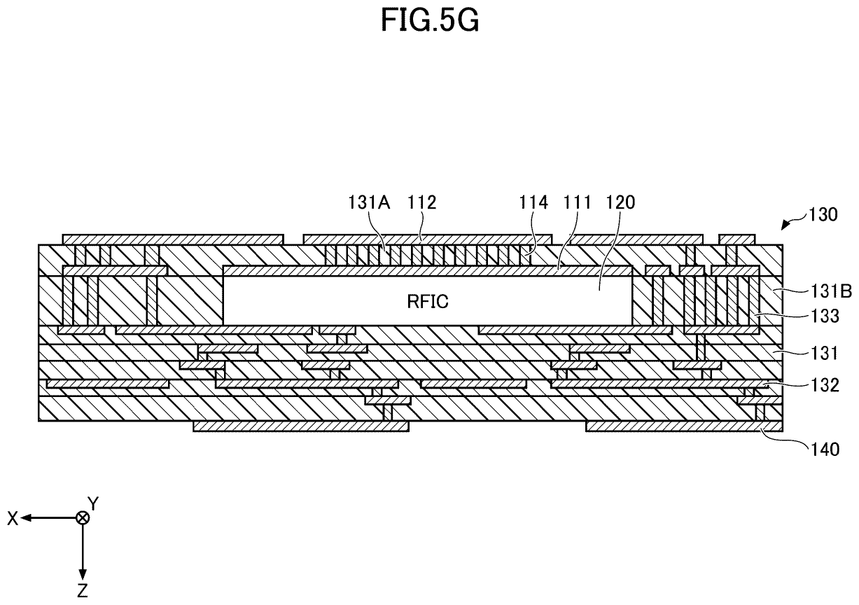

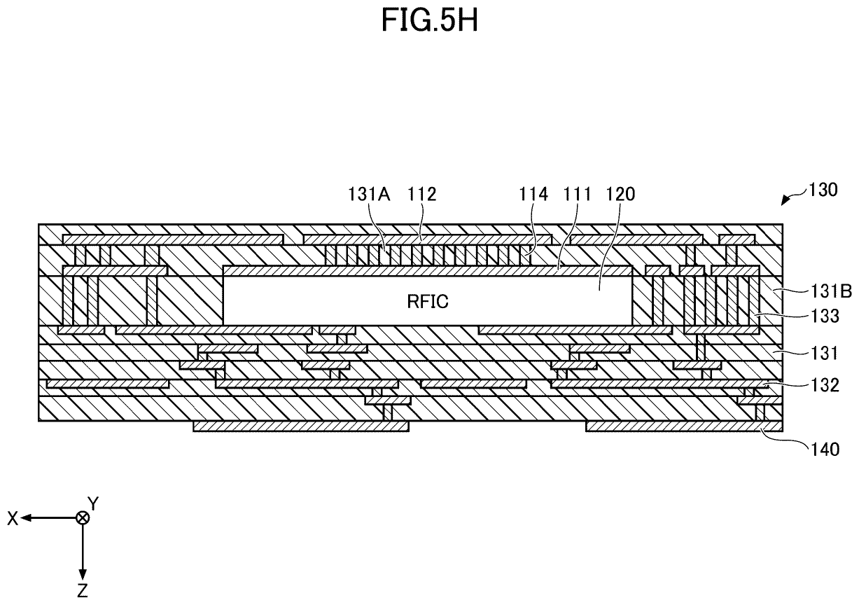

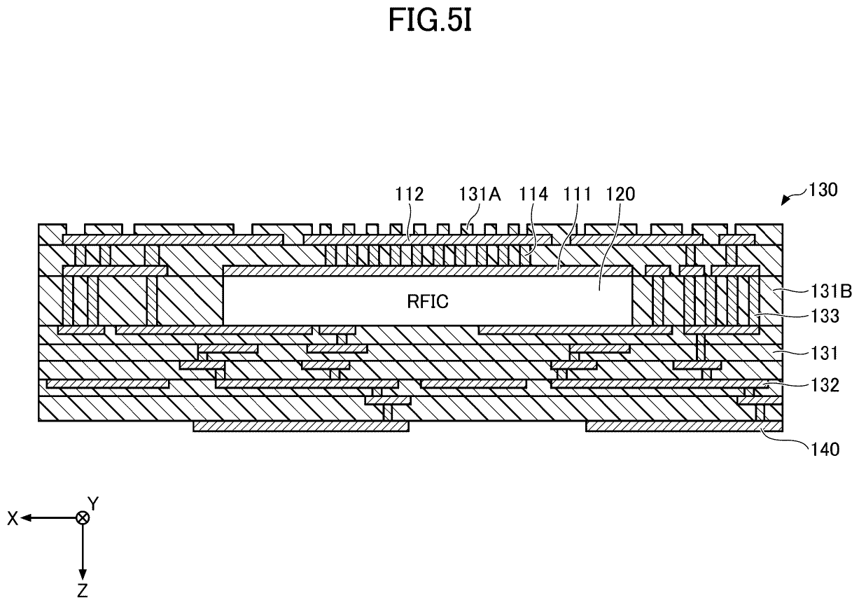

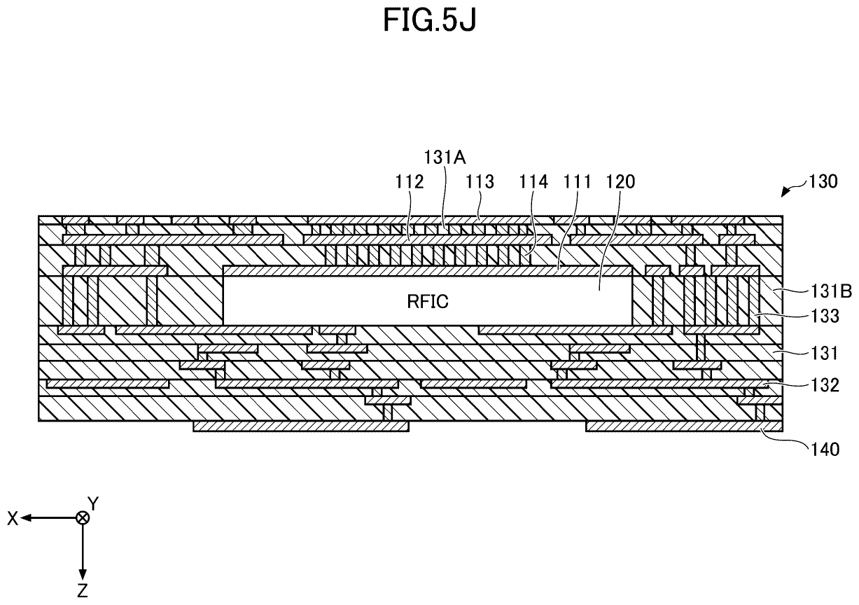

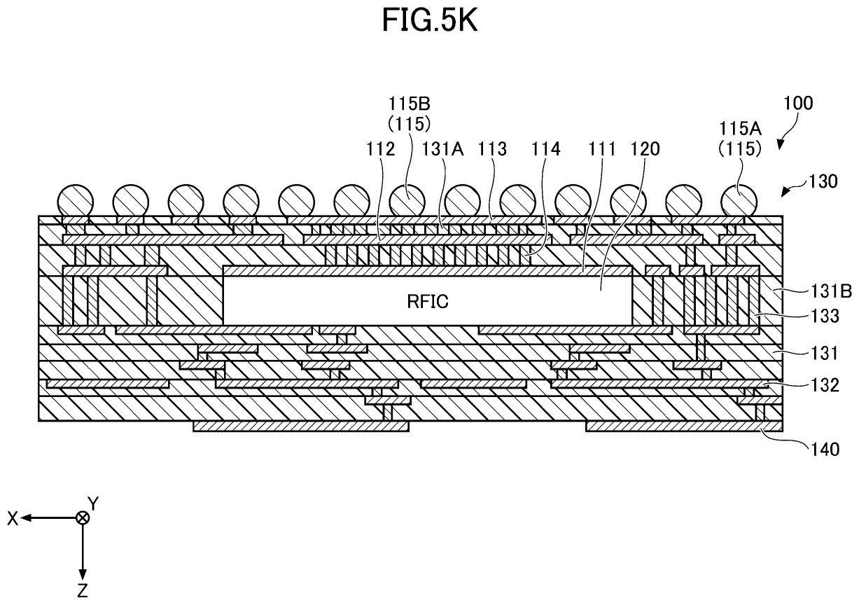

FIG. 5A to FIG. 5K are diagrams illustrating a manufacturing process of a semiconductor device 100 with an antenna.

In order to manufacture the semiconductor device 100 with an antenna, as an example, first, as illustrated in FIG. 5A, a portion of a wiring board 130 located on the antenna 140 side relative to a semiconductor chip 120, and an antenna 140 are fabricated. FIG. 5A illustrates an orientation that is upside down with respect to that of FIG. 1, and thus the antenna 140 is located on the lower surface side.

Specifically, a plurality of insulating layers 131, a plurality of interconnect layers 132, a plurality of vias 133, and the antenna 140 are fabricated by a redistribution layer manufacturing process (build-up manufacturing process)

Next, as illustrated in FIG. 5B, the semiconductor chip 120 is mounted by flip-chip bonding using copper pillars.

Next, as illustrated in FIG. 5C, an insulating layer 131B having the same height as the semiconductor chip 120, and vias 133 in the insulating layer 131B are fabricated. In a case where the insulating layer 131B is formed of a molding material, the insulating layer 131B having the same height as the semiconductor chip 120 may be fabricated by using a mold or the like. The vias 133 can be fabricated by forming openings in the insulating layer 131B with a laser and performing a plating process to fill the openings.

Next, as illustrated in FIG. 5D, a metal layer 111 and an interconnect layer 132 may be fabricated on the semiconductor chip 120 and the insulating layer 131B, respectively, by a redistribution layer manufacturing process. The metal layer 111 and the interconnect layer 132 may be patterned by forming a copper layer on the semiconductor chip 120 and the insulating layer 131B by sputtering, performing photolithography, and then performing etching.

Next, as illustrated in FIG. 5E, an insulating layer 131 is deposited on the metal layer 111. As an example, the insulating layer 131 can be fabricated by attaching an insulating sheet and then performing a firing process.

Next, as illustrated in FIG. 5F, an insulating layer 131A is fabricated. The insulating layer 131A may be fabricated by forming, in the insulating layer 131 fabricated in FIG. 5E, openings for vias 114 with a laser.

Next, as illustrated in FIG. 5G, vias 114 and a metal layer 112 are fabricated. The vias 114 can be fabricated by performing a plating process to fill the openings of the insulating layer 131A. The metal layer 112 can be fabricated by forming a copper layer by sputtering on the insulating layer 131A in which the vias 114 are formed, performing photolithography, and then performing patterning by etching.

Next, as illustrated in FIG. 5H, an insulating layer 131 is deposited on the metal layer 112. As an example, the insulating layer 131 can be fabricated by attaching an insulating sheet and then performing a firing process.

Next, as illustrated in FIG. 5I, a second insulating layer 131A is fabricated. The insulating layer 131A may be fabricated by forming, in the insulating layer 131 fabricated in FIG. 5H, openings for vias 114 with a laser.

Next, as illustrated in FIG. 5J, vias 114 and a metal layer 113 are fabricated. The vias 114 can be fabricated by performing a plating process to fill the openings of the second insulating layer 131A. The metal layer 113 can be fabricated by forming a copper layer by sputtering on the second insulating layer 131A in which the vias 114 are formed, performing photolithography, and then performing patterning by etching.

Finally, as illustrated in FIG. 5K, BGA terminals 150A are placed on an interconnect layer 132 and BGA terminals 150B are placed on the metal layer 113. As a result, the semiconductor device 100 with an antenna is obtained. At this time, the BGA terminals 150A are placed on terminals 132A (see FIG. 2) of the interconnect layer 132. Because the BGA terminals 150A and the BGA terminals 150B use common BGA terminals 150, the BGA terminals 150A and 150B can be placed by placing the BGA terminals 150 on a plurality of terminals 132A of the interconnect layer 132 and at a plurality of positions on the metal layer 113 at an equal pitch in the X direction and the Y direction.

<Method of Manufacturing Semiconductor Device 100 with Antenna According to Modification>

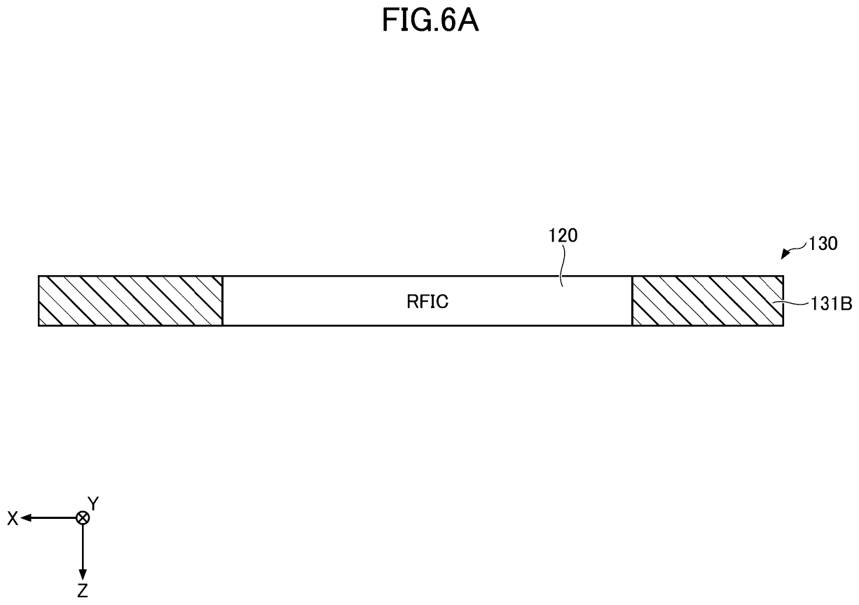

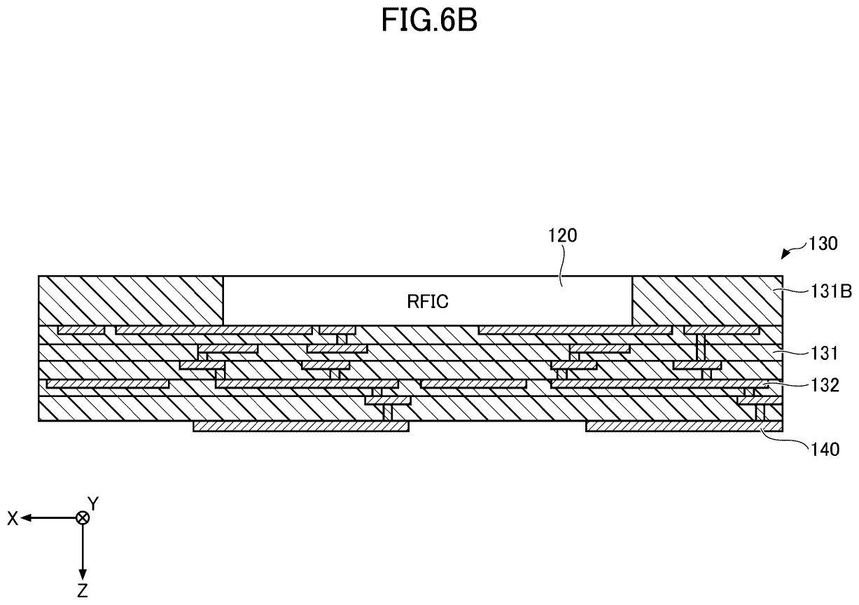

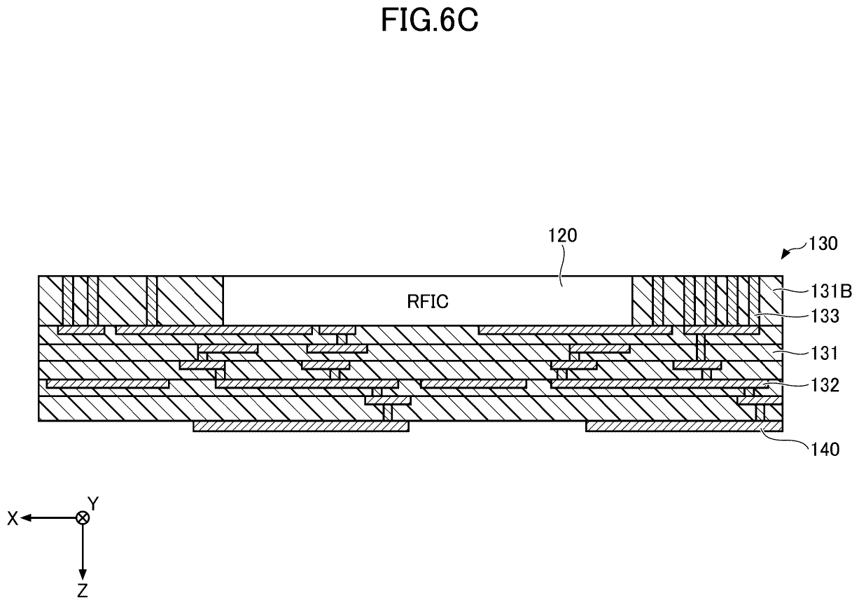

FIG. 6A to FIG. 6C are diagrams illustrating a manufacturing process of a semiconductor device 100 with an antenna according to a modification. Specifically, FIG. 6A to FIG. 6C illustrates manufacturing steps according to a modification of the manufacturing steps illustrated in FIG. 5A to FIG. 5C.

First, as illustrated in FIG. 6A, an insulating layer 131B having the same height as a semiconductor chip 120 is fabricated by using a mold or the like.

Next, as illustrated in FIG. 6B, a portion of a wiring board located on the antenna 140 side relative to the semiconductor chip 120, and an antenna 140 are fabricated. FIG. 6B illustrates an orientation that is upside down with respect to that of FIG. 1, and thus the antenna 140 is located on the lower surface side. However, in reality, with the +Z side of the antenna 140 facing upward, a plurality of insulating layers 131, a plurality of interconnect layers 132, a plurality of vias 133, and the antenna 140 are fabricated on the semiconductor chip 120 and the insulating layer 131B by a redistribution layer manufacturing process (build-up manufacturing process).

Next, as illustrated in FIG. 6C, vias 133 in the insulating layer 131B are fabricated. The vias 133 can be fabricated by forming openings in the insulating layer 131B with a laser and performing a plating process to fill the openings.

When the manufacturing step of FIG. 6C is completed, the same configuration as that obtained when the manufacturing step of FIG. 5C is completed can be obtained. Thus, the semiconductor device 100 with an antenna can be manufactured by performing manufacturing steps of FIG. 5D to FIG. 5K after the manufacturing step of FIG. 6C.

<Semiconductor Devices 100A and 100B with Antennas According to Modifications of Embodiment>

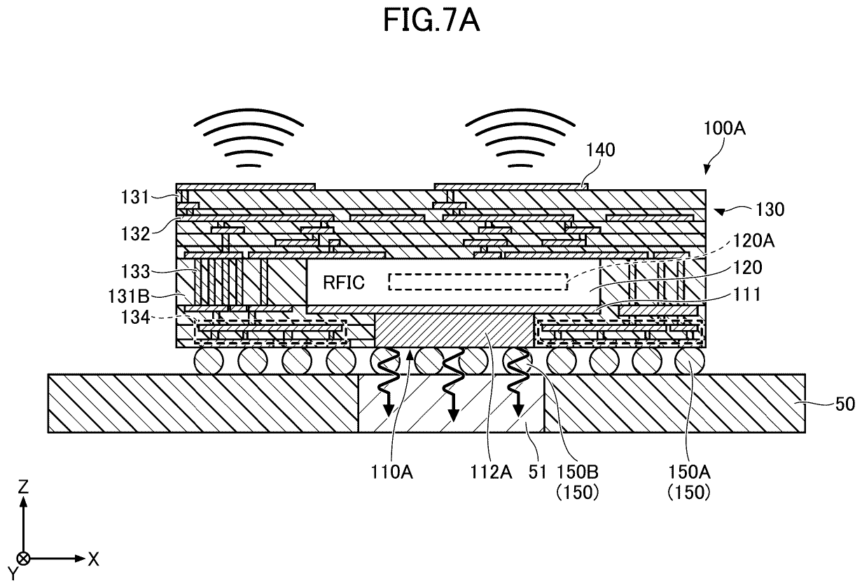

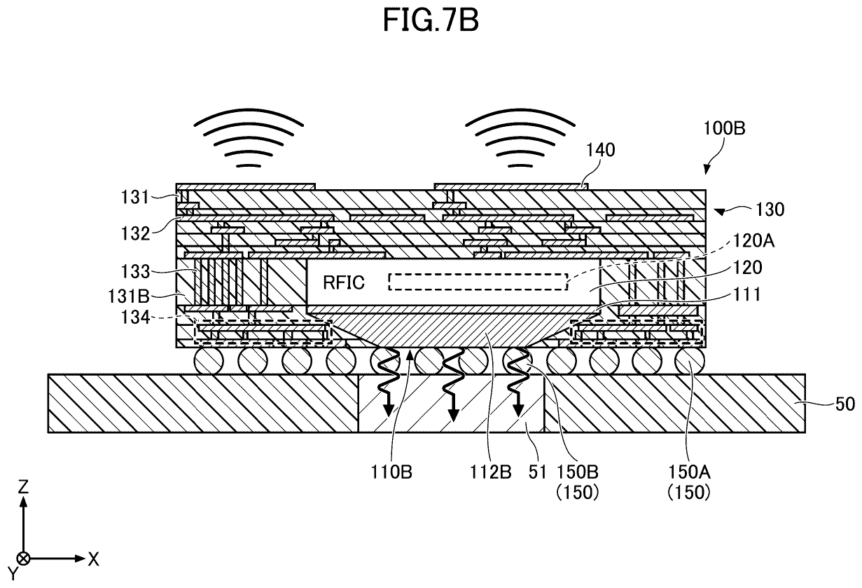

FIG. 7A and FIG. 7B are diagrams illustrating examples of configurations of semiconductor devices 100A and 100B with antennas according to modifications of the embodiment.

<Semiconductor Device 100A with Antenna (FIG. 7A)>

In the semiconductor device 100A with an antenna illustrated in FIG. 7A, a configuration of a heat dissipation part 110A differs from the configuration of the heat dissipation part 110 of the semiconductor device 100 with an antenna illustrated in FIG. 1 to FIG. 3.

The heat dissipation part 110A of the semiconductor device 100A with an antenna includes a metal layer 111 and a heat dissipation plate 112A. The heat dissipation part 110A includes the heat dissipation plate 112A implemented by a metal plate, instead of the metal layers 112 and 113, the vias 114, and the insulating layer 131A of the heat dissipation part 110 of the semiconductor device 100 with an antenna illustrated in FIG. 1 to FIG. 3.

The heat dissipation plate 112A has a rectangular parallelepiped shape, has the same size as the metal layers 112 and 113 in a plan view, and has a thickness equal to a height from the lower surface of the metal layer 111 to the lower surface of the metal layer 113 of the heat dissipation part 110.

Similar to the heat dissipation plate 51, the heat dissipation plate 112A is preferably formed of a metal having high thermal conductivity, and may be formed of a metal such as aluminum or copper, for example. The heat dissipation plate 112A as described above may be bonded to the lower surface of the metal layer 111 by soldering or the like. Then, BGA terminals 150B may be bonded to the lower surface of the heat dissipation plate 112A, and the heat dissipation plate 112A and the heat dissipation plate 51 may be connected to each other via the BGA terminals 150B.

The heat dissipation part 110A is connected to the heat dissipation plate 51 only via the BGA terminals 150B. Heat from the heat dissipation part 110A is transmitted to the heat dissipation plate 51 via the BGA terminals 150B and is dissipated from the heat dissipation plate 51 into the air. Further, some heat is dissipated from the heat dissipation part 110A and the BGA terminals 150B into the air.

The heat dissipation part 110A is connected to the heat dissipation plate 51 of the RF board 50 through the shortest path by the BGA terminals 150B connected to the lower surface of the metal layer 113. Thus, the heat dissipation part 110A is connected to the heat dissipation plate 51 with a low thermal resistance. Therefore, heat from the heat dissipation part 110A can be efficiently dissipated to the outside of the semiconductor device 100A with an antenna.

Similar to the semiconductor device 100 with an antenna having the configuration illustrated in FIG. 3, the semiconductor device 100A with an antenna illustrated in FIG. 7A can secure a heat dissipation path while securing a current path.

<Semiconductor Device 100B with Antenna (FIG. 7B)>

The semiconductor device 100B with an antenna illustrated in FIG. 7B includes a heat dissipation part 110B, instead of the heat dissipation part 110A of the semiconductor device 100A with an antenna illustrated in FIG. 7A. Instead of the heat dissipation plate 112A having the rectangular parallelepiped shape of the heat dissipation part 110A, the heat dissipation part 110B includes a heat dissipation plate 112B implemented by a metal plate having an inverted trapezoidal shape in an XZ plane view and a YZ plane view. Although FIG. 7B illustrates the shape of the heat dissipation plate 112B in an XZ plane view, the shape of the heat dissipation plate 112B in a YZ plane view is also an inverted trapezoidal shape.

The semiconductor device 100B with an antenna is similar to the semiconductor device 100A with an antenna illustrated in FIG. 7A, except that the shape of the heat dissipation plate 112B differs from the shape of the heat dissipation plate 112A of the heat dissipation part 110A of the semiconductor device 100A with an antenna illustrated in FIG. 7A.

Similar to the semiconductor device 100 with an antenna having the configuration illustrated in FIG. 3, the semiconductor device 100B with an antenna illustrated in FIG. 7B can secure a heat dissipation path while securing a current path.

Because the heat dissipation plate 112B has an inverted truncated square pyramid shape from its upper surface bonded to the metal layer 111 to its lower surface to which the BGA terminals 150B are bonded, the thermal resistance between the upper surface and the lower surface of the heat dissipation plate 112B is lower than that of the heat dissipation plate 112A illustrated in FIG. 7A. Accordingly, higher heat dissipation can be obtained.

<Method of Manufacturing Semiconductor Device 100B with Antenna>

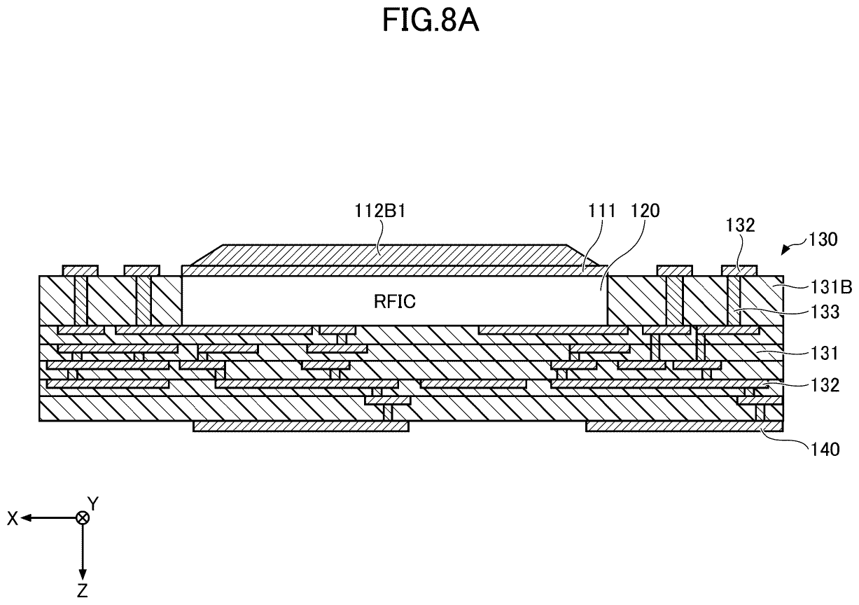

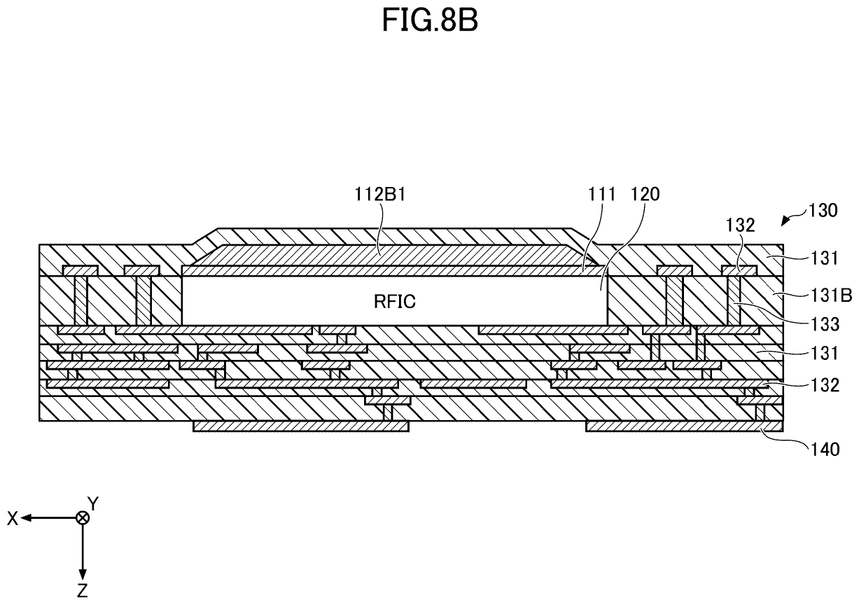

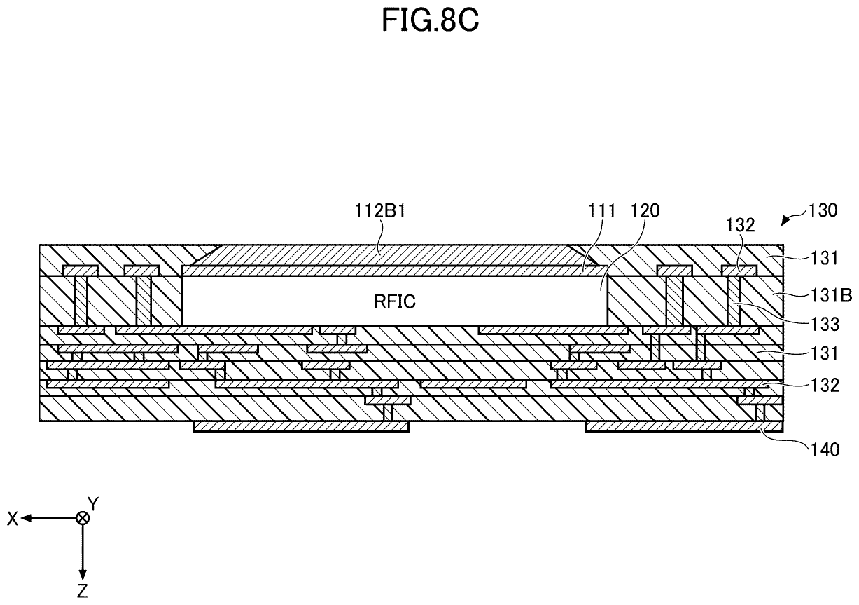

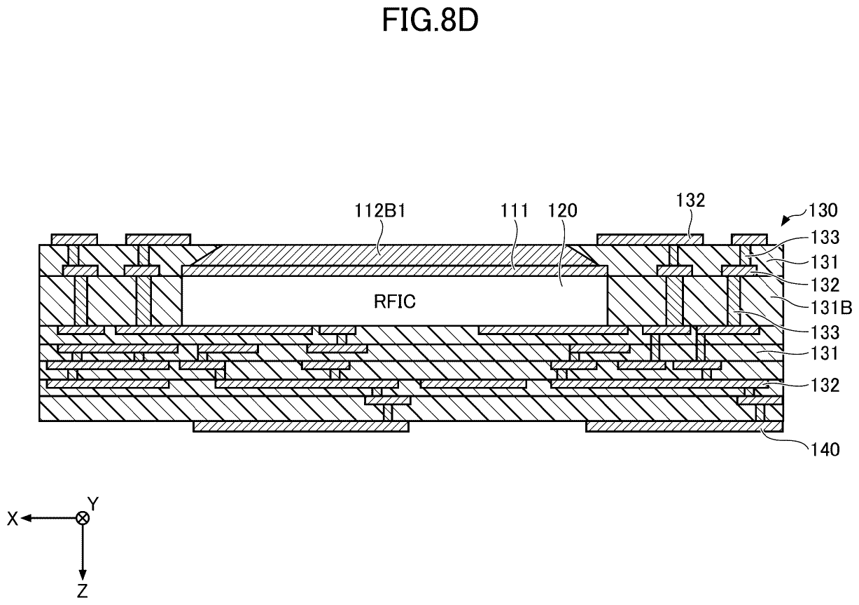

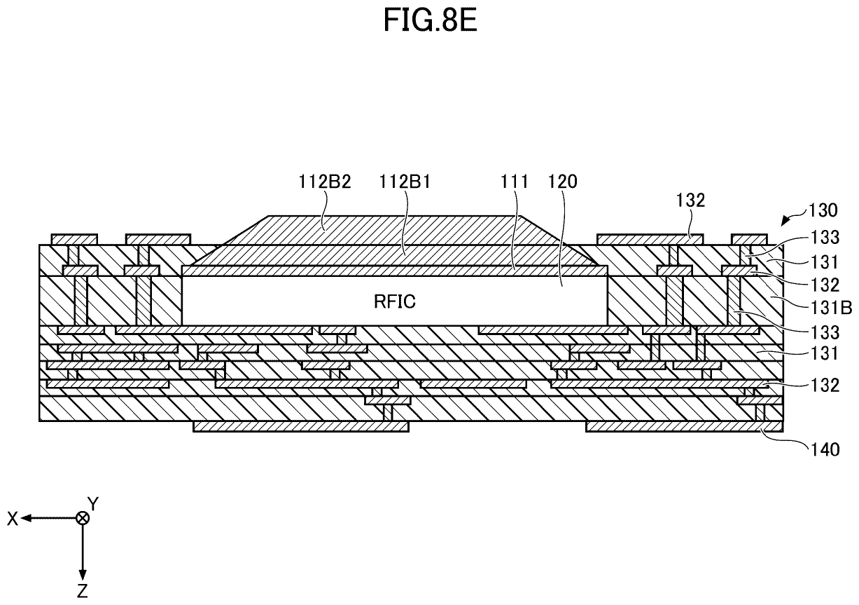

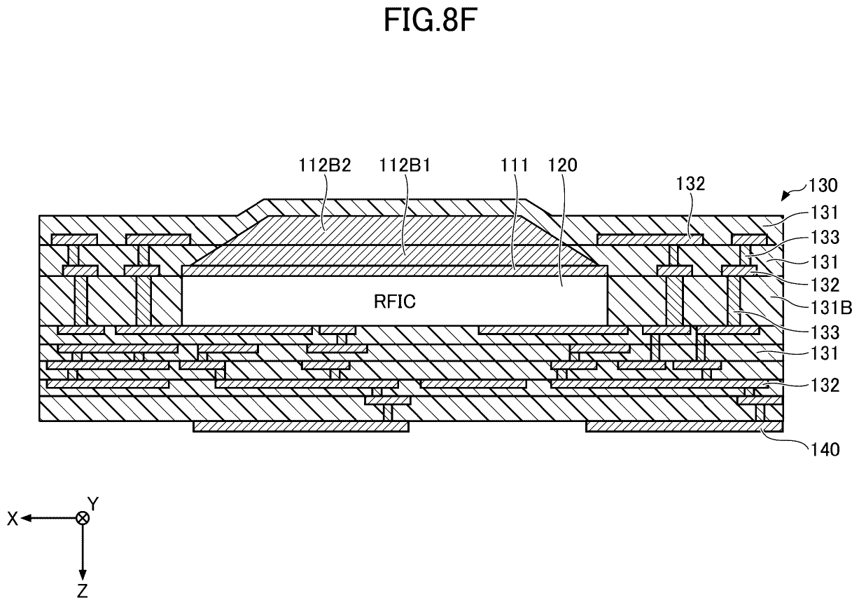

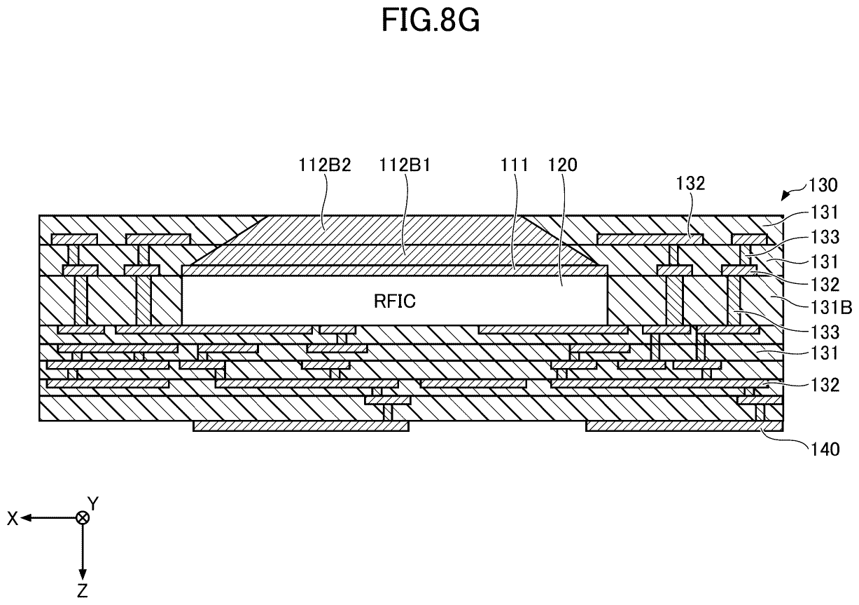

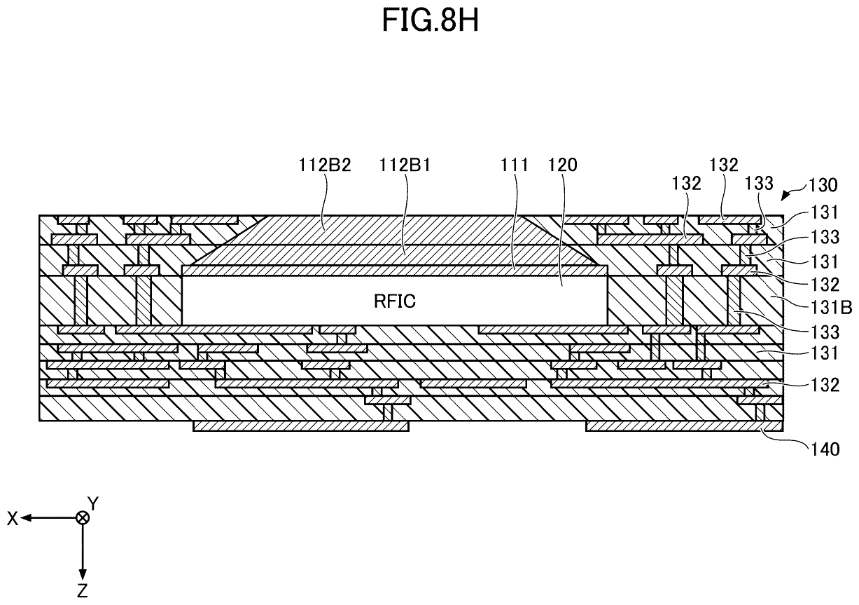

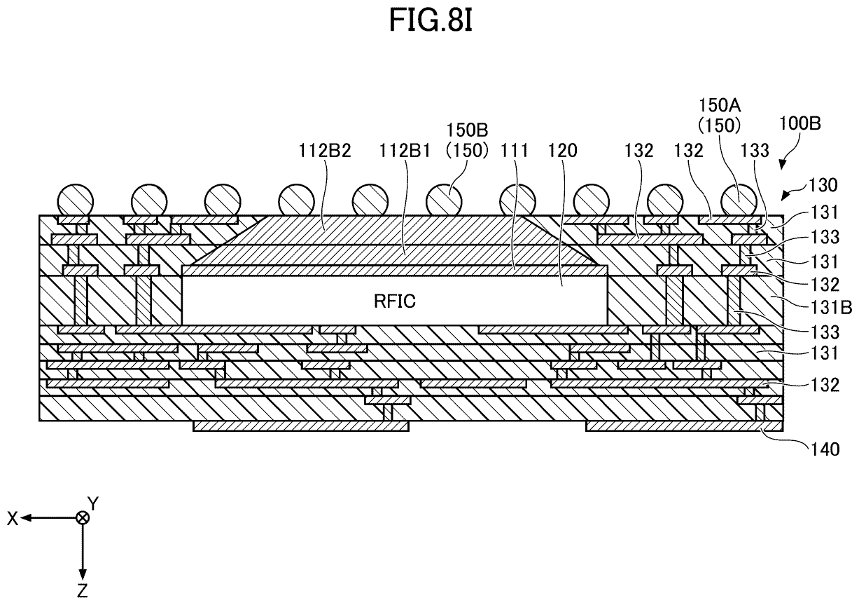

FIG. 8A to FIG. 8I are diagrams illustrating a manufacturing process of a semiconductor device 100B with an antenna. A manufacturing step illustrated in FIG. 8A is performed after the manufacturing step illustrated in FIG. 5D. That is, the semiconductor device 100B with an antenna is manufactured by performing the manufacturing steps illustrated in FIG. 5A to FIG. 5D and then manufacturing steps illustrated in FIG. 8A to FIG. 8I, for example. In the following, on the assumption that the manufacturing steps illustrated in FIG. 5A to FIG. 5D are completed, the manufacturing steps illustrated in FIG. 8A to FIG. 8I will be described.

As illustrated in FIG. 8A, a thin metal plate 112B1 having a truncated square pyramid is attached to the metal layer 111. The metal plate 112B1 may be attached to the metal layer 111 by bonding with solder, bonding with silver paste, or the like. The metal plate 112B1 corresponds to a first sheet obtained by slicing the heat dissipation plate 112B to be finally obtained in the Z direction.

Next, as illustrated in FIG. 8B, an insulating layer 131 is deposited on the metal plate 112B1, the insulating layer 131B, and the interconnect layers 132. As an example, the insulating layer 131 may be fabricated by attaching an insulating sheet and then performing a firing process.

Next, as illustrated in FIG. 8C, the insulating layer 131 deposited in FIG. 8B is polished until the upper surface of the metal plate 112B1 is exposed.

Next, as illustrated in FIG. 8D, vias 133 and an interconnect layer 132 are fabricated. The vias 133 can be fabricated by forming openings in the uppermost insulating layer 131 and performing a plating process to fill the openings. The interconnect layer 132 can be fabricated by forming a copper layer by sputtering on the insulating layer 131 in which the vias 133 are formed, performing photolithography, and then performing patterning by etching. The interconnect layer 132 is formed so as to avoid the metal plate 112B1.

Next, as illustrated in FIG. 8E, a thin metal plate 112B2 having a truncated square pyramid is attached to the metal plate 112B1. The metal plate 112B2 may be attached to the metal plate 112B1 by bonding with solder, bonding with silver paste, or the like. The metal plate 112B2 corresponds to a second sheet obtained by slicing the heat dissipation plate 112B to be finally obtained in the Z direction.

Next, as illustrated in FIG. 8F, an insulating layer 131 is deposited on the metal plate 112B2, the insulating layer 131 and the interconnect layer 132. As an example, the insulating layer 131 can be fabricated by attaching an insulating sheet and then performing a firing process.

Next, as illustrated in FIG. 8G, the insulating layer 131 deposited in FIG. 8F is polished until the upper surface of the metal plate 112B2 is exposed.

Next, as illustrated in FIG. 8H, vias 133 and an interconnect layer 132 are fabricated. The vias 133 can be fabricated by forming openings in the uppermost insulating layer 131 and performing a plating process to fill the openings. The interconnect layer 132 can be fabricated by forming a copper layer by sputtering on the insulating layer 131 in which the vias 133 are formed, performing photolithography, and then performing patterning by etching. The interconnect layer 132 is formed so as to avoid the metal plate 112B2.

Finally, as illustrated in FIG. 8I, BGA terminals 150A are placed on the interconnect layer 132 and BGA terminals 150B are placed on the metal layer 113. As a result, the semiconductor device 100B with an antenna is obtained. At this time, the BGA terminals 150A are placed on terminals 132A (see FIG. 2) of the interconnect layer 132. The manufacturing step illustrated in FIG. 8I is the same as that the manufacturing step illustrated in FIG. 5K.

### <Effects>

A semiconductor device 100 with an antenna according to the present disclosure includes: a semiconductor chip 120 having a lower surface, and a circuit surface located opposite the lower surface; a heat dissipation part 110 having a lower surface, and an upper surface located opposite the lower surface and in contact with the lower surface of the semiconductor chip 120; a wiring board 130 having a lower surface 130L located on a lower surface side of the heat dissipation part 110, an upper surface 130U located opposite the lower surface 130L, and a laminate in which an insulating layer 131 formed of a resin and an interconnect layers 132 formed of a metal are laminated, wherein the wiring board 130 covers side surfaces of the heat dissipation part 110 and of the semiconductor chip 120 and the circuit surface of the semiconductor chip 120, and exposes the lower surface of the heat dissipation part 110 at the lower surface 130L; and an antenna 140 provided on the upper surface 130U of the wiring board 130, wherein the wiring board 130 further includes terminals 132A provided in a region of the lower surface 130L located outward of an outer periphery of the semiconductor chip 120 in a plan view, and in a region of the lower surface 130L located inward of the outer periphery of the semiconductor chip 120 and outward of an outer periphery of the lower surface of the heat dissipation part 110 in the plan view, a first interconnect connecting the terminals 132A to a first terminal provided on the circuit surface of the semiconductor chip 120, and a second interconnect connecting the antenna 140 to a second terminal provided on the circuit surface of the semiconductor chip 120. As described above, the terminals 132A are provided in the region of the lower surface 130L located inward of the outer periphery of the semiconductor chip 120 and outward of the outer periphery of the lower surface of the heat dissipation part 110 in the plan view. That is, the terminals 132A can also be provided under the semiconductor chip 120, and thus a sufficient current path can be secured.

Accordingly, the semiconductor device 100 with an antenna that can secure a heat dissipation path while securing a current path can be provided.

Further, the heat dissipation part 110 may include a metal layer 111 provided on the lower surface of the semiconductor chip 120, and the upper surface of the heat dissipation part 110 may be a surface of the metal layer 111 in contact with the lower surface of the semiconductor chip 120. Because heat from the semiconductor chip 120 can be efficiently transmitted to the heat dissipation part 110 via the metal layer 111, heat dissipation is improved.

Further, the metal layer 111 may be provided on an entirety of the lower surface of the semiconductor chip 120. Because heat generated in the entire semiconductor chip 120 can be efficiently transmitted to the heat dissipation part 110 via the metal layer 111, heat dissipation is further improved.

Further, the heat dissipation part 110 may further include a metal layer 113 provided on a lower surface side of the heat dissipation part 110 relative to the metal layer 111, an insulating layer 131A provided between the metal layer 111 and the metal layer 113, and a plurality of vias 114 penetrating through the insulating layer 131A and connecting the metal layer 111 and the metal layer 113, the metal layer 111 and the metal layer 113 may be each formed together with the interconnect layer 132 of the wiring board 130, and the insulating layer 131A may be formed together with the insulating layer 131 of the wiring board 130. The heat dissipation part 110 can be simultaneously manufactured with the wiring board 130 by a semiconductor manufacturing process.

Further, a surface of the metal layer 113 located opposite the metal layer 111 may be the lower surface of the heat dissipation part 110. In a configuration in which the metal layer 113 is the lowermost metal layer of the heat dissipation part 110, a heat dissipation path can be secured while securing a current path.

Further, the metal layer 113 may be located inward of an outer periphery of the metal layer 111 in the plan view. Because the metal layer 113 to which BGA terminals 150B for a heat dissipation path are connected is provided in a smaller region, the number of BGA terminals 150A for a current path can be increased, and a current path can be further sufficiently secured. Further, by increasing the number of BGA terminals 150A for a current path, the signal transmission speed can be increased.

Further, the outer periphery of the metal layer 111 and an outer periphery of the metal layer 113 may each have a rectangular shape in the plan view. The BGA terminals 150A for a current path and the BGA terminals 150B for a heat dissipation path can be easily arranged, and the overall semiconductor device 100 with an antenna can be easily designed.

Further, the outer periphery of the metal layer 113 may have a projecting portion protruding outward or a recessed portion recessed inward in the plan view. The BGA terminals 150A and 150B can be arranged with a high degree of freedom so as to support various arrangements of the BGA terminals 150A for a current path or various arrangements of the BGA terminals 150B for a heat dissipation path.

Further, at least a portion of the metal layer 113 may be located outward of the outer periphery of the metal layer 111 in the plan view. As an example, a BGA terminal 150B disposed outward of the outer periphery of the metal layer 111 in the plan view may be connected to the ground or the like.

Further, the semiconductor device 100 may include a plurality of BGA terminals 150A and 150B of a same type, wherein the plurality of terminals 150A and 150B may be provided on the terminals 132A at the lower surface 130L, and provided on the lower surface of the heat dissipation part 110. Because the plurality of BGA terminals 150 of the same type can be provided on the terminals 132A at the lower surface 130L of the wiring board 130, and the lower surface of the heat dissipation section 110, the semiconductor device 100 with an antenna that can be reduced in size and easily manufactured can be provided. In addition, by using the plurality of BGA terminals 150 of the same type, the degree of freedom in arranging interconnects and vias in the wiring board 130 increases, and various circuits can be flexibly designed.

The wiring board 130 may include a redistribution layer. The size of the semiconductor device 100 with an antenna can be reduced, and also the first interconnect from the first terminal on the circuit surface, which is the upper surface of the semiconductor chip 120, to the lower surface 130L of the wiring board 130 can be easily fabricated.

A method of manufacturing a semiconductor device with an antenna according to the present disclosure, the semiconductor device including: a semiconductor chip 120 having a lower surface, and a circuit surface located opposite the lower surface; a heat dissipation part 110 having a lower surface, and an upper surface located opposite the lower surface and in contact with the lower surface of the semiconductor chip 120; a wiring board 130 having a lower surface 130L located on a lower surface side of the heat dissipation part 110, an upper surface 130U located opposite the lower surface 130L, and a laminate in which an insulating layer 131 formed of a resin and an interconnect layers 132 formed of a metal are laminated, wherein the wiring board 130 covers side surfaces of the heat dissipation part 110 and of the semiconductor chip 120 and the circuit surface of the semiconductor chip 120, and exposes the lower surface of the heat dissipation part 110 at the lower surface 130L; and the antenna 140 provided on the upper surface 130U of the wiring board 130, is provided. The method includes fabricating the wiring board 130 by laminating the insulating layer 131 formed of the resin and the interconnect layer 132 formed of the metal, wherein the fabricating of the wiring board 130 includes providing terminals 132A in a region of the lower surface 130L located outward of an outer periphery of the semiconductor chip 120 in a plan view, and in a region of the lower surface 130L located inward of the outer periphery of the semiconductor chip 120 and outward of an outer periphery of the lower surface of the heat dissipation part 110 in the plan view, fabricating a first interconnect connecting the terminals 132A to a first terminal provided on the circuit surface of the semiconductor chip 120, and fabricating a second interconnect connecting the antenna 140 to a second terminal provided on the circuit surface of the semiconductor chip 120. As described above, the terminals 132A are provided in the region of the lower surface 130L located inward of the outer periphery of the semiconductor chip 120 and outward of the outer periphery of the lower surface of the heat dissipation part 110 in the plan view. That is, the terminals 132A can also be provided under the semiconductor chip 120, and thus a sufficient current path can be secured.

Accordingly, the method of manufacturing the semiconductor device with an antenna that can secure a heat dissipation path while securing a current path can be provided.

Although semiconductor devices with antennas according to embodiments of the present disclosure and a method of manufacturing a semiconductor device with an antenna have been described above, the present disclosure is not limited to specific embodiments, and various modifications and changes can be made without departing from the scope of the claims.

All examples and conditional language provided herein are intended for pedagogical purposes of aiding the reader in understanding the invention and the concepts contributed by the inventors to further the art, and are not to be construed as limitation to such specifically recited examples and conditions, nor does the organization of such examples in the specification relate to a showing of superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device with an antenna, the semiconductor device comprising:
a semiconductor chip having a first chip surface, and a circuit surface located opposite the first chip surface;
a heat dissipation part having a first surface, and a second surface located opposite the first surface and in contact with the first chip surface of the semiconductor chip;
a wiring board having a first board surface located on a first surface side of the heat dissipation part, a second board surface located opposite the first board surface, and a laminate in which an insulating layer formed of a resin and an interconnect layer formed of a metal are laminated, wherein the wiring board covers side surfaces of the heat dissipation part and of the semiconductor chip and the circuit surface of the semiconductor chip, and exposes the first surface of the heat dissipation part at the first board surface; and
the antenna provided on the second board surface of the wiring board, wherein
the wiring board further includes
board connection parts provided in a region of the first board surface located outward of an outer periphery of the semiconductor chip in a plan view, and in a region of the first board surface located inward of the outer periphery of the semiconductor chip and outward of an outer periphery of the first surface of the heat dissipation part in the plan view,
a first interconnect connecting the board connection parts to a first terminal provided on the circuit surface of the semiconductor chip, and
a second interconnect connecting the antenna to a second terminal provided on the circuit surface of the semiconductor chip.

2. The semiconductor device with the antenna according to claim 1, wherein
the heat dissipation part includes a first metal layer provided on the first chip surface of the semiconductor chip, and
the second surface is a surface of the first metal layer in contact with the first chip surface.

3. The semiconductor device with the antenna according to claim 2, wherein the first metal layer is provided on an entirety of the first chip surface of the semiconductor chip.

4. The semiconductor device with the antenna according to claim 2, wherein
the heat dissipation part further includes
a second metal layer provided on a first surface side of the heat dissipation part relative to the first metal layer,
an interlayer insulating layer provided between the first metal layer and the second metal layer, and
a plurality of vias penetrating through the interlayer insulating layer and connecting the first metal layer and the second metal layer,
the first metal layer and the second metal layer are each formed together with the interconnect layer of the wiring board, and
the interlayer insulating layer is formed together with the insulating layer of the wiring board.

5. The semiconductor device with the antenna according to claim 4, wherein a surface of the second metal layer located opposite the first metal layer is the first surface of the heat dissipation part.

6. The semiconductor device with the antenna according to claim 4, wherein the second metal layer is located inward of an outer periphery of the first metal layer in the plan view.

7. The semiconductor device with the antenna according to claim 6, wherein the outer periphery of the first metal layer and an outer periphery of the second metal layer each have a rectangular shape in the plan view.

8. The semiconductor device with the antenna according to claim 6, wherein the outer periphery of the second metal layer has a projecting portion protruding outward or a recessed portion recessed inward in the plan view.

9. The semiconductor device with the antenna according to claim 5, wherein at least a portion of the second metal layer is located outward of the outer periphery of the first metal layer in the plan view.

10. The semiconductor device with the antenna according to claim 1, further comprising:
a plurality of connection terminals of a same type, wherein
the plurality of connection terminals are provided on the board connection parts at the first board surface, and provided on the first surface of the heat dissipation part.

11. The semiconductor device with the antenna according to claim 1, wherein the wiring board includes a redistribution layer.

12. A method of manufacturing a semiconductor device with an antenna, the semiconductor device including
a semiconductor chip having a first chip surface, and a circuit surface located opposite the first chip surface,
a heat dissipation part having a first surface, and a second surface located opposite the first surface and in contact with the first chip surface of the semiconductor chip,
a wiring board having a first board surface located on a first surface side of the heat dissipation part, a second board surface located opposite the first board surface, and a laminate in which an insulating layer formed of a resin and an interconnect layer formed of a metal are laminated, wherein the wiring board covers side surfaces of the heat dissipation part and of the semiconductor chip and the circuit surface of the semiconductor chip, and exposes the first surface of the heat dissipation part at the first board surface, and
the antenna provided on the second board surface of the wiring board, the method comprising:
fabricating the wiring board by laminating the insulating layer formed of the resin and the interconnect layer formed of the metal, wherein
the fabricating of the wiring board includes
providing board connection parts in a region of the first board surface located outward of an outer periphery of the semiconductor chip in a plan view, and in a region of the first board surface located inward of the outer periphery of the semiconductor chip and outward of an outer periphery of the first surface of the heat dissipation part in the plan view,
fabricating a first interconnect connecting the board connection parts to a first terminal provided on the circuit surface of the semiconductor chip, and
fabricating a second interconnect connecting the antenna to a second terminal provided on the circuit surface of the semiconductor chip.
